(19) United States
(12) Patent Application Publication
(10) Pub. No.: US 2004/0119080 A1
(43) Pub. Date: Jun. 24, 2004

(54) Semiconductor optical device

(76) Inventors: Jun-ichi Hashimoto, Yokohama-shi (JP); Tsukuru Katsuyama, Yokohama-shi (JP)

Correspondence Address: SMITH, GAMBRELL & RUSSELL, LLP, 1850 M STREET, N.W., SUITE 800, WASHINGTON, DC, 20036, US

(21) Appl. No.: 10/638,962

(22) Filed: Aug. 12, 2003

Related U.S. Application Data
(60) Provisional application No. 60/470,848, filed on May 16, 2003.

(30) Foreign Application Priority Data
Aug. 12, 2002 (JP) P2002-235101

(51) Int. Cl. H01L 27/15

(52) U.S. Cl. 257/85

(57) ABSTRACT

A semiconductor light-emitting device 1 comprises a first semiconductor layer 3, an active layer 5, a second semiconductor layer 7, a third semiconductor layer 9, and a current block semiconductor layer 11. The first semiconductor layer 3 is provided on the surface of GaAs semiconductor. The active layer 5 is provided on the first semiconductor layer 3. The second semiconductor layer 7 is provided on the active layer 5. The third semiconductor layer 9 is provided on the second semiconductor layer 7, and has a pair of side faces 9a, 9b. The current block semiconductor layer 11 is provided on the second semiconductor layer 7 and a pair of side faces 9a, 9b of the third semiconductor layer 9. The third semiconductor layer of a stripe form 9 extends along a predetermined axis. The current block semiconductor layer 11 has a conductivity type different from the third semiconductor layer 9. The active layer 5 is formed of III-V compound semiconductor including at least nitrogen as a V group member.

### RELATED APPLICATION DATA

The present application claims priority from U.S. Provisional Application No. 60/470,848 filed on May 16, 2003, the entirety of which is incorporated by reference herein for all purposes.

### BACKGROUND OF THE INVENTION

1. Field of the Invention

The present invention relates to a semiconductor optical device.

2. Related Background of the Invention

One of structures of semiconductor optical devices, such as a semiconductor laser device, is an buried ridge structure. FIG. 24 shows an example of the structure of a semiconductor laser device having a buried ridge structure. Referring to FIG. 24, an active layer 105 is provided on a lower cladding layer 103 formed on a substrate 101. A first upper cladding layer 107, which is a planar shape, is provided on the active layer 105, whereas a second upper cladding layer 109, which is a ridge shape, is provided on the first upper cladding layer 107. A current block layer 111 is provided on both sides of the second upper cladding layer 109. A contact layer 113 is provided on the current block layer 111 and the second upper cladding layer 109. For manufacturing a semiconductor laser device 100 of an buried ridge structure, its ridge part is formed by using wet etching. In this structure, the ridge part is formed throughout the second upper cladding layer 109, and thus inevitably the ridge part becomes high and the etching time for forming the ridge part becomes longer. It is not easy to control the shape of the ridge as the wet etching time becomes longer, thereby deteriorating the reproducibility and uniformity of laser characteristics. In order to improve the controllability of the ridge shape, various modifications and changes are needed in the etching process.

### SUMMARY OF THE INVENTION

FIG. 25A is a view showing a semiconductor optical device. This semiconductor light-emitting device 120 has a buried ridge structure different from the structure shown in FIG. 24. Referring to FIG. 25A, an active layer 125 is provided on a lower cladding layer 123 formed on a substrate 121. A first upper cladding layer 127 having a planar shape is provided on the active layer 125, whereas a second upper cladding layer 129 having a ridge shape is provided on the first upper cladding layer 127. A current block layer 131 is provided on both sides of the second upper cladding layer 129. A third upper cladding layer 133 and a contact layer 135 are provided on the current block layer 131 and the second upper cladding layer 129. Since only the second upper cladding layer 129 is formed into a ridge, this structure can reduce the height of the ridge part and shorten the etching time as compared with the structure shown in FIG. 24. Therefore, this structure has a technical advantage over the structure shown in FIG. 24 in that the controllability of the ridge shape is improved, thereby enhancing the reproducibility and uniformity of laser characteristics for laser devices on a wafer.

The semiconductor light-emitting device 120 having a buried ridge structure comprises the cladding layers and the current block layer. If the semiconductor material of the cladding layers is the same as that of the current block layer, there is no difference in refractive index between the cladding layers and the current block layer in lateral transverse directions. As a consequence, the transverse modes of the laser beam cannot be stably confined and the guiding of the laser beam becomes unstable. This semiconductor light-emitting device fails to exhibit stable emission beam characteristics. Hence, the semiconductor material of the cladding layers has to be different from that of the current block layer. In a semiconductor light-emitting device using an InP semiconductor as a semiconductor material for its cladding layers, candidates of semiconductor materials lattice-matching to the InP semiconductor are InGaAs and InGaAsP semiconductors. However, the refractive indices of InGaAs and InGaAsP semiconductors are higher than that of the InP semiconductor. FIG. 25B is a chart showing the refractive index taken along the line Q-Q of FIG. 25A. As shown in FIG. 25B, the refractive index of the current block layer 131 is higher than that of the ridge-shaped second upper cladding layer 129, so that lateral transverse modes are not stably confined within the stripe region of the semiconductor light-emitting device, whereby light generated in the active layer 125 spreads to the current block layer 131 outside the second upper cladding layer 129 to become the anti refractive index guiding mode. In the anti refractive index guiding mode, Far Field Pattern (FFP) of the semiconductor light-emitting device is likely to have multiple peaks and becomes unstable, and thus the semiconductor light-emitting device fails to achieve favorable optical coupling with an optical fiber. Also, there are other demerits such as a high threshold current due to a large quantity of light leaking from the stripe. Hence, what is needed is semiconductor light-emitting devices, such as semiconductor laser devices, which can enhance the confinement of transverse modes of laser light.

Therefore, it is an object of the present invention to provide a semiconductor optical device having a refractive index guiding structure which can stably confine transverse modes.

According to one aspect of the present invention, a semiconductor optical device comprises a first semiconductor layer of a first conductivity type, an active layer, a second semiconductor layer of a second conductivity type, a third semiconductor layer of the second conductivity type, and a current block semiconductor portion. The first semiconductor layer is provided on a surface of GaAs semiconductor. The active layer is provided on the first semiconductor layer. The second semiconductor layer is provided on the active layer. The second semiconductor layer includes a primary surface having a first area and second areas. The first area is provided between the second areas. The third semiconductor layer is provided on the first area of the second semiconductor layer. The current block semiconductor portion is provided on the second areas of the second semiconductor layer. The refractive index of the third semiconductor layer is higher than that of the current block semiconductor portion. The active layer is formed of a III-V compound semiconductor containing at least a nitrogen element as a V group member.

The semiconductor optical device according to the present invention further comprises a fourth semiconductor layer. The fourth semiconductor layer includes a III-V compound semiconductor. The fourth semiconductor layer is provided between the active layer and at least one of the first and second semiconductor layers. The III-V compound semiconductor exhibits a photoluminescence wavelength value between a photoluminescence wavelength value exhibited by the active layer and a photoluminescence wavelength value exhibited by one of the first and second semiconductor layers.

The semiconductor optical device according to the present invention further comprises a first SCH semiconductor layer and a second SCH semiconductor layer. The first SCH semiconductor layer is provided between the second semiconductor layer and the active layer. The second SCH semiconductor layer is provided between the active layer and the first semiconductor layer.

The semiconductor optical device according to the present invention further comprises a fourth semiconductor layer. The fourth semiconductor layer includes a III-V compound semiconductor. The fourth semiconductor layer is provided in at least following arrangements: between the second SCH semiconductor layer and the first semiconductor layer; between the first SCH semiconductor layer and the second semiconductor layer. The III-V compound semiconductor of the fourth semiconductor layer exhibits a photoluminescence wavelength value between a photoluminescence wavelength value exhibited by the SCH layers and a photoluminescence wavelength value exhibited by one of the first and second semiconductor layers.

The semiconductor optical device according to the present invention further comprises an etching stop layer provided between the second and third semiconductor layers.

In the semiconductor optical device, the etching stop layer has a pair of side faces. The current block semiconductor portion is provided on each side face of the etching stop layer.

The semiconductor optical device according to the present invention further comprises a fifth semiconductor layer and a contact layer. The fifth semiconductor layer is provided on the third semiconductor layer and the current block semiconductor portion. The contact layer is provided on the fifth semiconductor layer.

In the semiconductor optical device, each of the second and third semiconductor layers and current block semiconductor portion is formed of an (Al_{X}Ga_{1-X})_{Y}In_{1-Y}P semiconductor (0≦X≦1). The fifth semiconductor layer is formed of (Al_{X}Ga_{1-X})_{Y}In_{1-Y}P semiconductor (0≦X≦1).

In the semiconductor optical device, each of the second and third semiconductor layers and current block semiconductor portion is formed of an Al_{X}Ga_{1-X}As semiconductor (0≦X≦1). The fifth semiconductor layer is formed of Al_{X}Ga_{1-X}As semiconductor (0≦X≦1).

According to another aspect of the present invention, a semiconductor optical device comprises a first semiconductor layer of a first conductivity type, an active layer, a second semiconductor layer, and a current block semiconductor portion.

The first semiconductor layer is provided on a surface of GaAs semiconductor. The active layer is provided on the first semiconductor layer. The active layer has a primary surface. The primary surface has a first area and second areas. The first area is provided between the second areas. The second semiconductor layer is provided on the first area of the active layer. The second semiconductor layer has a pair of side faces. The current block semiconductor portion is provided on the second areas of the active layer. The current block semiconductor portion has first and second current block semiconductor layers. The first current block semiconductor layer has a conductivity type different from that of the second current block semiconductor layer. The current block semiconductor portion is provided on the pair of side faces of the second semiconductor layer. The refractive index of the second semiconductor layer is higher than the refractive indices of the first and second current block semiconductor layers.

In the semiconductor optical device, the active layer is formed of a III-V compound semiconductor containing at least nitrogen element as a V group member.

In the semiconductor optical device, the active layer is provided to generate light having a wavelength of longer than 0.9 micrometers.

The semiconductor optical device according to the present invention further comprises a third semiconductor layer including a III-V compound semiconductor. The third semiconductor layer is provided between the active layer and at least one of the first and second semiconductor layers. The III-V compound semiconductor exhibits a photoluminescence wavelength value between a photoluminescence wavelength value exhibited by the active layer and a photoluminescence wavelength value exhibited by one of the first and second semiconductor layers.

The semiconductor optical device according to the present invention further comprises a first SCH semiconductor layer provided between the active layer and the current block semiconductor portion and second semiconductor layer. The second SCH semiconductor layer is provided between the active layer and the first semiconductor layer.

The semiconductor optical device according to the present invention further comprises a third semiconductor layer including a III-V compound semiconductor. The third semiconductor layer is provided in at least one of the following arrangements: between the first SCH semiconductor layer and the second semiconductor layer; between the second SCH semiconductor layer and the first semiconductor layer. The III-V compound semiconductor exhibits a photoluminescence wavelength value between a photoluminescence wavelength value exhibited by the SCH layers and a photoluminescence wavelength value exhibited by one of the first and second semiconductor layer.

The semiconductor optical device according to the present invention further comprises an etching stop layer provided between the active layer and the second semiconductor layer.

In the semiconductor optical device, the etching stop layer has a pair of side faces. The current block semiconductor portion is provided on each side face of the etching stop layer.

The semiconductor optical device according to the present invention further comprises a fourth semiconductor layer and a contact layer. The fourth semiconductor layer is provided on the second semiconductor layer and the current block semiconductor portion. The contact layer is provided on the fourth semiconductor layer.

In the semiconductor optical device, each of the second and fourth semiconductor layers and first and second current block semiconductor layers is formed of an (Al_{X}Ga_{1-X})_{Y}In_{1-Y}P semiconductor (0≦X≦1).

In the semiconductor optical device, each of the second and fourth semiconductor layers and first and second current block semiconductor layers is formed of an Al_{X}Ga_{1-X}As semiconductor (0≦X≦1).

In the semiconductor optical device, the III-V compound semiconductor in the active layer includes at least gallium as a III group member and further includes at least arsenic as a V group member.

In the semiconductor optical device, each of the first and second SCH semiconductor layers is formed of at least one of an Al_{X}Ga_{1-X}As semiconductor (0≦X≦1) and a Ga_{X}In_{1-X}As_{Y}P_{1-Y} semiconductor.

In the semiconductor optical device, the surface of GaAs semiconductor is provided by one of a GaAs semiconductor layer or a gallium arsenide substrate.

In the semiconductor optical device, the semiconductor optical device includes at least one of a semiconductor laser, a semiconductor optical amplifier device and an electroabsorption type modulator, and may be a semiconductor optical integrated device.

The above-described object and other objects, features, and advantages of the present invention will become apparent more easily in the detailed description of the preferred embodiments of the present invention which will be described below with reference to the accompanying drawings.

### BRIEF DESCRIPTION OF THE DRAWINGS

FIG. 1 is a perspective view showing a semiconductor light-emitting device in accordance with a first embodiment;

FIG. 2A is a sectional view, taken along the line I-I shown in FIG. 1, of the semiconductor light-emitting device.

FIG. 2B is a chart showing the refractive index taken, along the line II-II of FIG. 2A, of the semiconductor light-emitting device. FIG. 2C is a chart showing the refractive index, taken along the line III-III of FIG. 2A, of the semiconductor light-emitting device;

FIG. 3A is a sectional view showing the semiconductor light-emitting device in accordance with a modified example of the first embodiment. FIG. 3B is a chart showing the forbidden bandgap of the semiconductor light-emitting device taken along the line IV-IV of FIG. 3A. FIG. 3C is a chart showing the refractive index along the line IV-IV of FIG. 3A;

FIG. 4A is a sectional view showing the semiconductor light-emitting device in accordance with a modified example of the first embodiment. FIG. 4B is a chart showing widths of the forbidden band of a first semiconductor layer, an active layer, an additional semiconductor layer, and a second semiconductor layer taken along the line V-V of FIG. 4A;

FIG. 5A is a sectional view showing the semiconductor light-emitting device in accordance with a modified example of the first embodiment. FIG. 5B is a chart showing widths of the forbidden band of a first semiconductor layer, an active layer, an additional semiconductor layer, first and second SCH semiconductor layers, and a second semiconductor layer taken along the line VI-VI of FIG. 5A;

FIG. 6 is a sectional view showing the semiconductor light-emitting device in accordance with a modified example of the first embodiment;

FIG. 7 is a sectional view showing the semiconductor light-emitting device in accordance with a modified example of the first embodiment;

FIG. 8 is a sectional view showing the semiconductor light-emitting device in accordance with a modified example of the first embodiment;

FIG. 9 is a sectional view showing the semiconductor light-emitting device in accordance with a modified example of the first embodiment;

FIG. 10 is a perspective view showing a semiconductor light-emitting device in accordance with a second embodiment;

FIG. 11A is a sectional view, taken along the line VII-VII of FIG. 10, of the semiconductor light-emitting device. FIG. 11B is a chart showing the refractive index, taken along the line VIII-VIII of FIG. 11A, of the semiconductor light-emitting device. FIG. 11C is a chart showing the refractive index, taken along the line IX-IX of FIG. 11A, of the semiconductor light-emitting device;

FIG. 12 is a sectional view showing the semiconductor light-emitting device in accordance with a modified example of the second embodiment;

FIG. 13 is a sectional view showing the semiconductor light-emitting device in accordance with a modified example of the second embodiment;

FIG. 14 is a sectional view showing the semiconductor light-emitting device in accordance with a modified example of the second embodiment;

FIG. 15 is a sectional view showing the semiconductor light-emitting device in accordance with a modified example of the second embodiment;

FIG. 16 is a sectional view showing the semiconductor light-emitting device in accordance with a modified example of the second embodiment;

FIG. 17 shows current versus optical output characteristics of a GaInNAs laser with temperature as a parameter;

FIG. 18 shows slope efficiency characteristics versus temperature of a GaInNAs laser;

FIG. 19 shows threshold current characteristics versus temperature of a GaInNAs laser;

FIG. 20 shows the Far Field Pattern of the GaInNAs laser;

FIG. 21 shows the temperature dependence of chip gain of the GaInNAs optical amplifier;

FIG. 22 shows the temperature dependence of chip gain of an InP/InGaAsP semiconductor optical amplifier;

FIG. 23 shows the dependence of peak chip gain on temperature for the GaInNAs and InP/InGaAsP semiconductor optical amplifiers;

FIG. 24 is a sectional view showing a semiconductor laser device having a buried ridge structure; and

FIG. 25A is a sectional view showing a semiconductor laser device having a buried ridge structure, and FIG. 25B is a chart showing the refractive index taken along the line Q-Q of FIG. 25A.

### DESCRIPTION OF THE PREFERRED EMBODIMENTS

The teachings of the present invention will readily be understood in view of the following detailed descriptions with reference to the accompanying drawings illustrated by way of example. Referring to the accompanying drawings, embodiments of the semiconductor optical device according to the present invention will now be explained. When possible, parts identical to each other will be referred to with numerals identical to each other.

First Embodiment

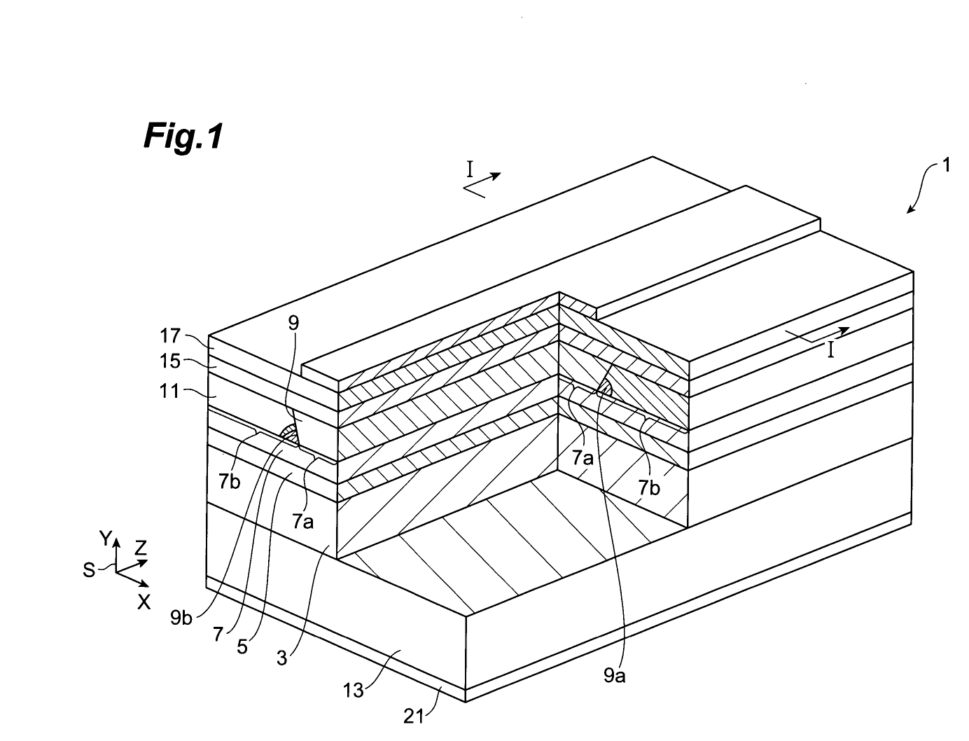

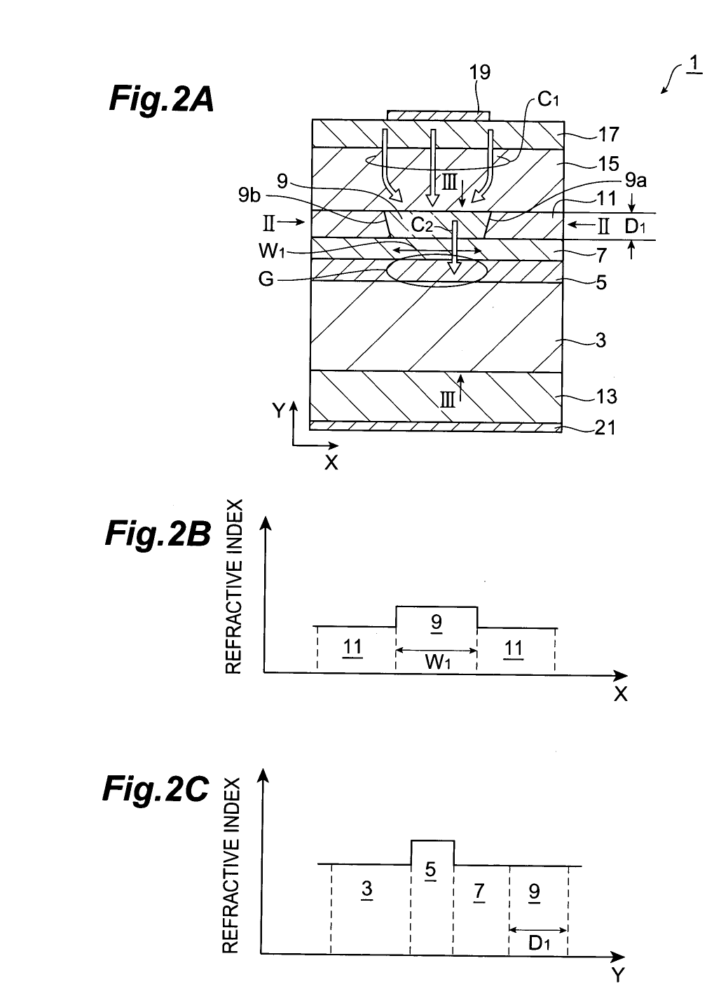

FIG. 1 is a perspective view showing the semiconductor light-emitting device in accordance with a first embodiment. XYZ coordinate system S is depicted in FIG. 1. FIG. 2A is a sectional view taken along the line I-I shown in FIG. 1. FIG. 2B is a chart showing the refractive index taken along the line II-II of FIG. 2A. Referring to FIGS. 1 and 2A, a semiconductor light-emitting device 1, such as a semiconductor laser device of buried ridge type, is illustrated. If the buried ridge structure is used, a semiconductor laser device having a high reliability can be manufactured by use of a simple manufacturing process.

The semiconductor light-emitting device 1 comprises a first semiconductor layer 3, an active layer 5, a second semiconductor layer 7, a third semiconductor layer 9, and a current block semiconductor layer 11. The first semiconductor layer 3 is provided on a surface of GaAs semiconductor. The active layer 5 is provided on the first semiconductor layer 3. The second semiconductor layer 7 is provided on the active layer 5. The third semiconductor layer 9 is provided on the second semiconductor layer 7, and has a pair of side faces 9a, 9b. The current block semiconductor layer 11 is provided on the second semiconductor layer 7 and on the side faces 9a and 9b of the third semiconductor layer 9. The second semiconductor layer 7 has a first area 7a and second areas 7b on its primary surface. The first area 7a are provided between the second areas 7b. The third semiconductor layer 9 is provided on the first area 7a of the second semiconductor layer 7. The current block layer 11 is provided on the second areas 7b of the second semiconductor layer 7. The third semiconductor layer 9 extends in a direction of a predetermined axis, and has a stripe form. The current block semiconductor layer 11 is provided on both sides of the third semiconductor layer 9. The conductivity type of the current block semiconductor layer 11 is different from that of the third semiconductor layer 9.

The active layer 5 is constituted by a III-V type compound semiconductor including at least nitrogen element as a member in the V group (referred to as V group member). Since the active layer 5 is constituted by a III-V type compound semiconductor including nitrogen (N) of a V group member and is provided on the surface of GaAs semiconductor, the semiconductor optical device 1 can be manufactured by use of the current block semiconductor layer 11 and the third semiconductor layer 9 having a refractive index higher than that of the current block semiconductor layer 11. Consequently, as shown in FIG. 2B, the refractive index of the third semiconductor layer 9 can be made higher than that of the current block semiconductor layer 11. This configuration realizes a guide mode of a refractive index guiding type, thereby making it possible to enhance the confinement of lateral transverse modes. As a result, laser beam characteristics are stabilized, the optical coupling to optical fiber is improved, and the threshold current is lowered.

FIG. 2C is a chart showing the refractive index taken along the line III-III in FIG. 2A. As shown in FIG. 2C, the refractive index of the active layer 5 is higher than the refractive indices of the first semiconductor layer 3, second semiconductor layer 7 and third semiconductor layer 9, and is higher than the refractive index of the current block semiconductor layer 11. The first semiconductor layer 3 has a first conductivity type and works as a lower cladding layer. The second semiconductor layer 7 has a second conductivity type and works as a first upper cladding layer. The third semiconductor layer 9 has the second conductivity type and works as a second upper cladding layer. The active layer 5 emits light in response to the injection of carriers thereto.

The semiconductor light-emitting device 1 further comprises a substrate 13. The substrate 13 mounts the first semiconductor layer 3, the active layer 5, the second semiconductor layer 7, the third semiconductor layer 9, and the current block semiconductor layer 11 on its primary surface. In the semiconductor optical device 1, an example of the substrate 13 may be a gallium arsenide substrate, but the surface of GaAs semiconductor may be provided by a GaAs semiconductor layer provided on a substrate different from a gallium arsenide substrate, e.g., a silicon substrate.

The semiconductor optical device 1 may further comprise a semiconductor layer 15 provided on the third semiconductor layer 9 and current block layer 11. The semiconductor layer 15 is useful for reducing the height of the ridge-shaped semiconductor portion. When the height D₁ of the ridge-shaped semiconductor portion decreases, fluctuations in the width (referred to as Symbol W₁ in FIG. 2A) of the ridge-shaped semiconductor portion can be reduced in its manufacture. The refractive index of the semiconductor layer 15 is lower than that of the active layer 5. The semiconductor layer 15 is useful as a third upper cladding layer.

The semiconductor optical device 1 may further comprise a contact layer 17 provided on the third upper cladding layer 15, and an electrode 19 provided on the contact layer 17. The contact layer 17 has a carrier concentration higher than that of the third upper cladding layer 15, and has a forbidden band narrower than that of the third upper cladding layer 15. Because of the higher carrier concentration and the narrower forbidden band of the contact layer 17, ohmic contact is realized between the contact layer 17 and the electrode 19. The semiconductor optical device 1 may further comprise an electrode 21 on the rear face of the substrate 13. One of the electrodes 19 and 21 acts as an anode, whereas the other acts as a cathode.

The electrode 19 has a stripe form extending in the direction of the predetermined axis and is provided on just above the ridge-shaped semiconductor layer 9. Therefore, carriers C₁ from the electrode 19 flow through the semiconductor layers 17 and 15. Carriers C₂ can flow through the semiconductor layer 9, but not through the current block layer 11. That is, due to the action of the current block layer 11, the carriers C₂ flow into the semiconductor layer 9. Carriers from the electrode 19 are supplied to the active layer 5 only through the semiconductor layer 9 having side surfaces on which the current block layer 11 is provided. The semiconductor optical device 1 can generate light in a major region G of the active layer just below the ridge-shaped semiconductor layer 9.

In the semiconductor optical device 1, each of the first semiconductor layer 3, active layer 5, second semiconductor layer 7, third semiconductor layer 9, current block semiconductor layer 11, semiconductor layer 15 and contact layer 17 is formed of a III-V compound semiconductor. Each of the second semiconductor layer 7, third semiconductor layer 9, current block semiconductor layer 11, and semiconductor layer 15 may be formed of an (Al_{X}Ga_{1-X})_{Y}In_{1-Y}P semiconductor (0≦X≦1) which lattice-matches to GaAs semiconductor. Alternatively, in the semiconductor optical device 1, each of the second semiconductor layer 7, third semiconductor layer 9, current block semiconductor layer 11, and semiconductor layer 15 may be formed of an Al_{X}Ga_{1-X}As semiconductor (0≦X≦1). Using these semiconductor materials for the semiconductor optical device 1 satisfies both of the requirement for the refractive index between the current block semiconductor layer and cladding layers, and the requirement for the carrier confinement between the active layer and cladding layers.

In a first example of the semiconductor light-emitting device 1,

the first semiconductor layer 3: n-type AlGaInP semiconductor and/or GaInP semiconductor;

the active layer 5: undoped (referred to as “un-”) GaInNAs semiconductor, un-GaNAs semiconductor, un-GaNAsSb semiconductor, un-GaNAsP semiconductor, un-GaNAsSbP semiconductor, un-GaInNAsSb semiconductor, un-GaInNAsP semiconductor, and/or un-GaInNAsSbP semiconductor;

the second semiconductor layer 7: p-type AlGaInP semiconductor and/or GaInP semiconductor;

the third semiconductor layer 9: p-type AlGaInP semiconductor and/or GaInP semiconductor;

the current block semiconductor layer 11: n-type AlGaInP semiconductor;

the substrate 13: heavily-doped n-type GaAs substrate;

the semiconductor layer 15: p-type AlGaInP semiconductor and/or GaInP semiconductor; and

the contact layer 17: p-type GaAs semiconductor.

In a second example of the semiconductor light-emitting device 1,

the first semiconductor layer 3: n-type AlGaAs semiconductor;

the active layer 5: un-GaInNAs semiconductor, un-GaNAs semiconductor, un-GaNAsSb semiconductor, un-GaNAsP semiconductor, un-GaNAsSbP semiconductor, un-GaInNAsSb semiconductor, un-GaInNAsP semiconductor, and/or un-GaInNAsSbP semiconductor;

the second semiconductor layer 7: p-type AlGaAs semiconductor;

the third semiconductor layer 9: p-type AlGaAs semiconductor;

the current block semiconductor layer 11: n-type AlGaAs semiconductor;

the substrate 13: heavily-doped n-type GaAs substrate;

the semiconductor layer 15: p-type AlGaAs semiconductor; and

the contact layer 17: p-type GaAs semiconductor.

In these examples, the compositions of the third semiconductor layer 9 and current block semiconductor layer 11 are determined such that the third semiconductor layer 9 has a refractive index higher than that of the current block semiconductor layer 11. The first semiconductor layer 3, the second semiconductor layer 7, the third semiconductor layer 9, and the current block semiconductor layer 11 are formed of semiconductor materials which lattice-match to GaAs semiconductor.

As mentioned above, the III-V compound semiconductor of the active layer in the semiconductor optical device 1 preferably includes at least gallium element (Ga) acting as a III group member, and at least arsenic element (As) and nitrogen element (N) acting as V group members. Due to the active layer made of the above material, the active layer 5 can be formed on a surface of GaAs, so that the semiconductor optical device 1 can be made from the current block semiconductor layer 11 and the third semiconductor layer 9 that has a refractive index higher than that of the current block semiconductor layer 11. The semiconductor optical device 1 has a structure allowing a lateral transverse mode to propagate in a light guiding mode of a refractive index guiding type, and the semiconductor optical device 1 can enhance the confinement of the lateral transverse mode into the stripe region.

Examples of the III-V compound semiconductor including at least nitrogen, gallium, and arsenic are GaNAs and GaInNAs semiconductors. They are new materials which have recently been developed. If the composition of their constituent elements (Ga, In, N, and As) is properly adjusted to form semiconductor materials, the formed materials may lattice-match to GaAs semiconductor or may have a lattice constant close to the lattice constant of GaAs semiconductor (a lattice mismatch within the range of ±2 percent), and the semiconductor optical device 1 can generate light having a wavelength of longer than 0.9 micrometers. Therefore, a long-wavelength semiconductor light-emitting device can be realized on a GaAs semiconductor layer or GaAs substrate.

GaNAs and GaInNAs semiconductors or the like may further contain antimony (Sb) and/or phosphorus (P) as a V group element. Antimony can act as a so-called surfactant to suppress the three-dimensional growth of GaInNAs semiconductors, thereby acting to improve the crystalline quality of GaInNAs semiconductors. Phosphorus acts to reduce local strains within GaNAs and GaInNAs semiconductors, and/or acts to increase the content of nitrogen atoms taken into the crystal. GaInNAsP semiconductors are advantageous in that they do not have miscibility gap which makes it difficult to grow the relevant crystals.

Further, the active layer 5 may be formed from an un-GaInAs semiconductor and/or an un-GaInAsP. If a GaInAs semiconductor is used as a material for the active layer 5, the light emitting device 1 can generate oscillation light having a wavelength of 0.9 micrometers or longer. Therefore, the semiconductor optical device 1 according to the present invention can be used for high power semiconductor lasers, which can generate light having a wavelength in a 0.98 micrometer band, acting as light sources for pumping an erbium-doped fiber amplifier. The semiconductor optical device 1 can be also used for high power semiconductor lasers, which can generate light having a wavelength in a 1.017 micrometer band, acting as light sources for pumping a praseodymium-doped optical fiber amplifier. In these semiconductor lasers, laser oscillation conditions, such as threshold gain, are improved due to a compressive strain exerted on the GaInAs semiconductor portion. Consequently, remarkable improvements can be obtained in the high output performance of the semiconductor lasers. If a GaInAsP semiconductor is used as a material for the active layer 5, the composition of the GaInAsP semiconductor can be adjusted to change strain of the GaInAsP semiconductor as is the case with GaInAs semiconductor. The composition of GaInAsP semiconductor can be widely changed as compared to that of GaInAs semiconductor because the number of the constituent elements of GaInAsP semiconductor is greater than that of GaInAs semiconductor. Therefore, the degree of freedom in the design of the semiconductor lasers can further be enhanced.

In the semiconductor optical device 1, the active layer 5 may have a quantum well structure. Examples of the quantum well structure are SQW and MQW structures, but the structure of the active layer is not limited thereto. The well layer may use the same material as that of the active layer 5, for example, whereas the barrier layer may use the same material as the material of SCH layers, such as an AlGaAs or GaInAsP semiconductor.

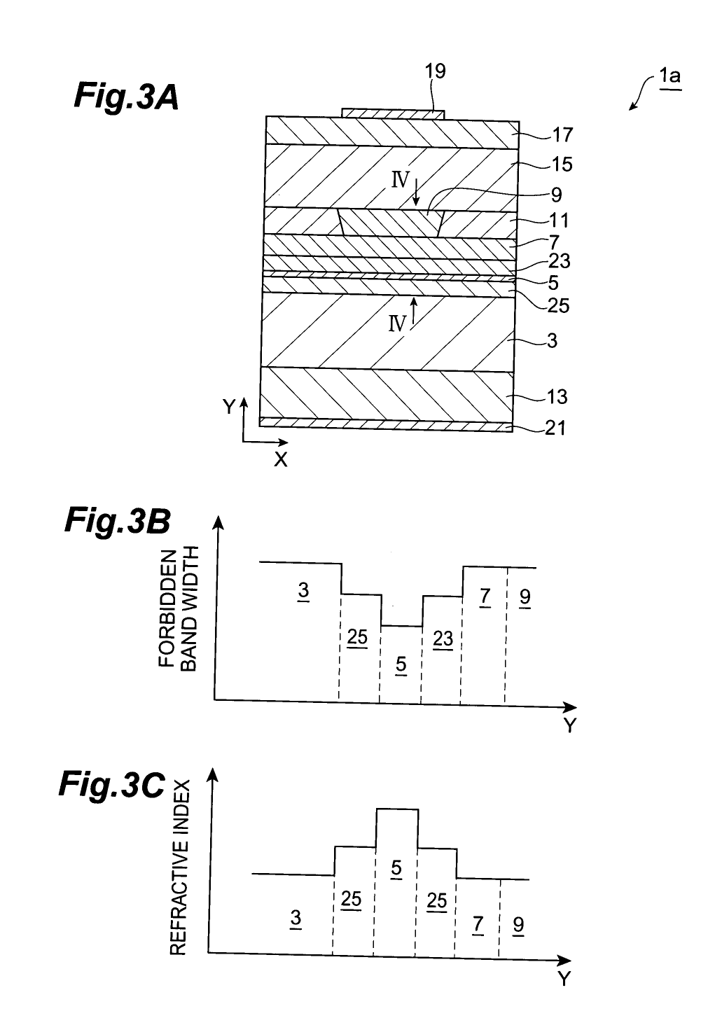

FIG. 3A is a sectional view showing the semiconductor light-emitting device in accordance with a modified example of the first embodiment. This semiconductor light-emitting device 1a has a separate confinement heterostructure (SCH). The semiconductor optical device 1a may further comprise a first SCH semiconductor layer 23 and a second SCH semiconductor layer 25 in addition to the configuration of the semiconductor light-emitting device 1. The first SCH semiconductor layer 23 is provided between the second semiconductor layer 7 and the active layer 5. The second SCH semiconductor layer 25 is provided between the active layer 5 and the first semiconductor layer 3. FIG. 3B is a chart showing the forbidden band width of the semiconductor light-emitting device taken along the line IV-IV of FIG. 3A. FIG. 3C is a chart showing the refractive index of the semiconductor light-emitting device taken along the line IV-IV of FIG. 3A. In the semiconductor light-emitting device 1a, carriers (electrons and holes) are confined in the active layer 5 with the aid of the first and second semiconductor layers 3 and 7 and SCH semiconductor layers 23 and 25 as shown in FIG. 3B. As shown in FIG. 3C, light in the semiconductor light-emitting device 1a is confined in the active layer 5 and SCH semiconductor layers 23 and 25 with the aid of the first and second semiconductor layers 3 and 7. That is, the first and second SCH semiconductor layers 23 and 25 make it possible to confine current and light separately from each other.

In the semiconductor optical device 1a, each of the first SCH semiconductor layer 23 and second SCH semiconductor layer 25 may be constituted by at least one of an Al_{X}Ga_{1-X}As semiconductor (0≦X≦1) and a GaInAsP semiconductor. If these materials are used, the refractive indexes of the SCH semiconductor layers 23 and 25 can be set to values between the refractive indices of the first semiconductor layer 3 and second semiconductor layer 7 and the refractive index of the active layer 5 to confine the light in the active layer 5, and the photoluminescence wavelength values of the SCH semiconductor layers 23 and 25 can be set to values between the photoluminescence wavelength values of the first semiconductor layer 3 and second semiconductor layer 7 and the photoluminescence wavelength value of the active layer 5 to confine carriers in the active layer 5.

In first and second examples of the semiconductor light-emitting device 1a,

the first and second SCH semiconductor layers 23 and 25: un-AlGaAs semiconductor, un-GaAs semiconductor, and/or un-Ga_{X}In_{1-X}As_{Y}P_{1-Y} semiconductor.

The GaInAsP semiconductor is provided so as to lattice-match to GaAs semiconductor.

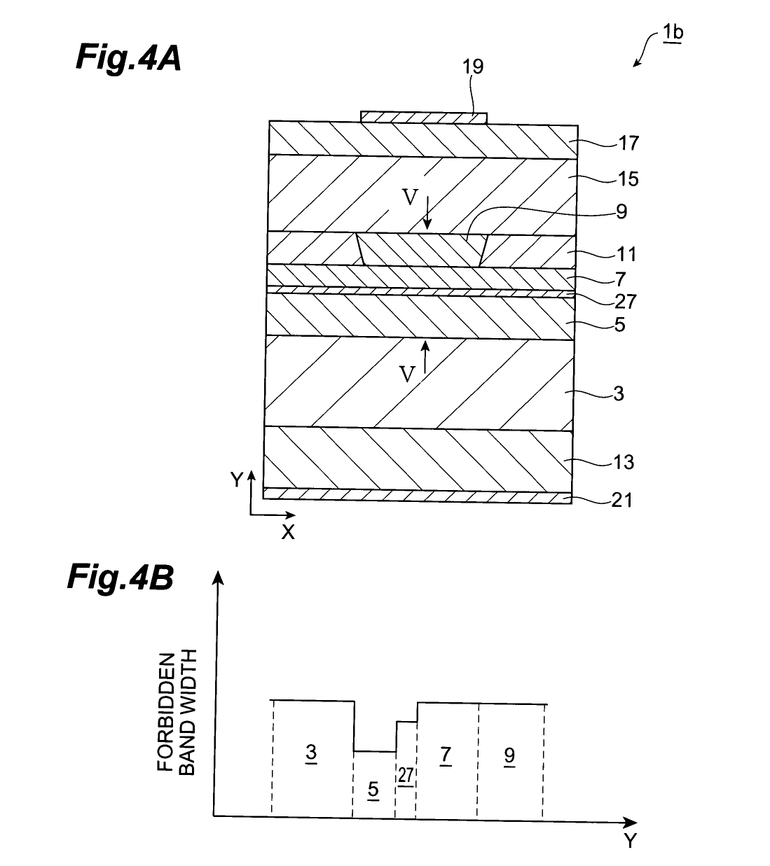

FIG. 4A is a sectional view showing the semiconductor light-emitting device in accordance with a modified example of the first embodiment. The semiconductor light-emitting device 1b may further comprise another semiconductor layer 27 in addition to the configuration of the semiconductor light-emitting device 1. The other semiconductor layer 27 is provided between the active layer 5 and the second semiconductor layer 7 and/or between the active layer 5 and the first semiconductor layer 3, and is made of material including a III-V compound semiconductor. This III-V compound semiconductor exhibits the photoluminescence wavelength value between the photoluminescence wavelength value exhibited by the active layer 5 and the photoluminescence wavelength values exhibited by the first semiconductor layer 3 and the second semiconductor layer 7. The semiconductor layer 27 has the same conductivity type as the semiconductor layers (the first semiconductor layer 3 and second semiconductor layer 7) adjacent to the semiconductor layer 27.

FIG. 4B is a chart showing the forbidden band width of the semiconductor light-emitting device taken along the line V-V of FIG. 4A, and illustrates the forbidden band widths of the first semiconductor layer 3, the active layer 5 made of a single semiconductor film, the other semiconductor layer 27, and the second semiconductor layer 7. If the combination of the active layer 5, the other semiconductor layer 27 and the second semiconductor layer 7 satisfy the relationship of photoluminescence wavelengths corresponding to these forbidden band widths as shown in FIG. 4B, this combination can decrease the amount of spikes or notches caused by the hetero-barrier between the active layer 5 and second semiconductor layer 7, and alleviates the hetero-barrier between the active layer 5 and the second semiconductor layer 7.

In first and second examples of the semiconductor light-emitting device 1c,

the semiconductor layer 27: p-type AlGaAs semiconductor, p-type AlGaInP semiconductor, p-type GaInP semiconductor, and/or p-type GaInAsP semiconductor.

If the semiconductor light-emitting device 1c comprises the hetero-barrier alleviating layer 27, the hetero-barrier alleviating layer 27 can reduce the electric resistance caused by spikes or notches occurring at a heterojunction. In particular, if a hetero-barrier alleviating layer is provided in a p-type semiconductor region of the semiconductor light-emitting device 1c, the p-type hetero-barrier alleviating layer can lower a large hetero-barrier against holes and thus decreases electrical resistance caused thereby. The hetero-barrier alleviating layer 27 can lower the amount of heat generated by the semiconductor light-emitting device, thereby improving device characteristics and long-term reliability of the semiconductor optical device. The hetero-barrier alleviating layer may be, however, provided in an n-type semiconductor region as well.

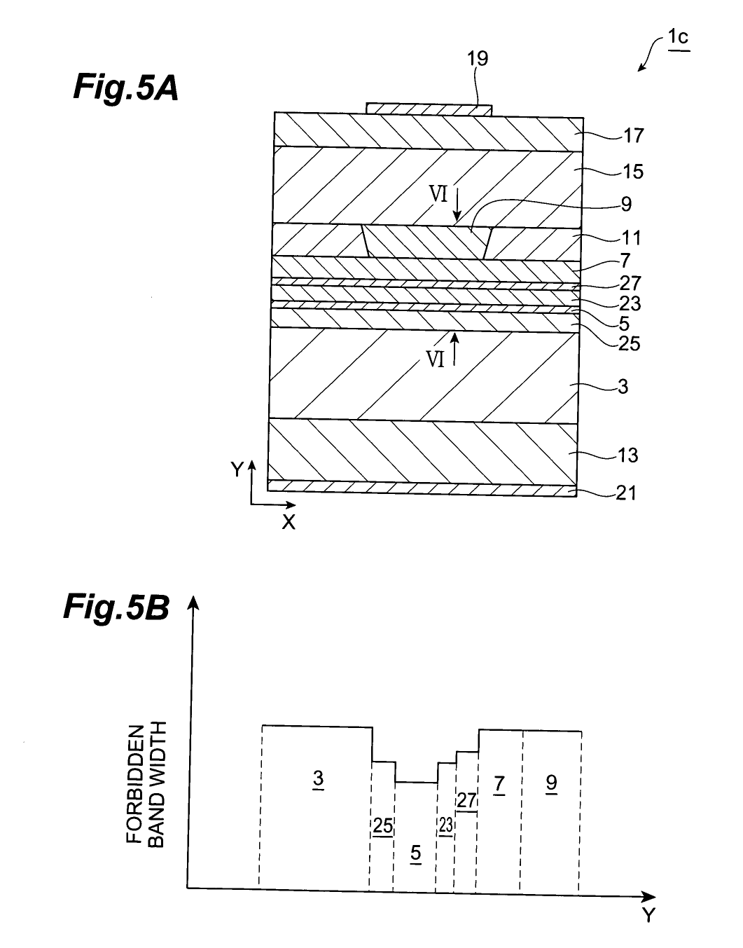

FIG. 5A is a sectional view showing the semiconductor light-emitting device in accordance with another modified example of the first embodiment. The semiconductor light-emitting device 1c may further comprise a first SCH semiconductor layer 23, a second SCH semiconductor layer 25, and another semiconductor layer 27 in addition to the configuration of the semiconductor light-emitting device 1. The other semiconductor layer 27 is provided between the second SCH semiconductor layer 25 and the first semiconductor layer 3 and/or between the first SCH semiconductor layer 23 and the second semiconductor layer 7. The semiconductor layer 27 has the same conductivity type as that of the semiconductor layers (the first semiconductor layer 3 and second semiconductor layer 7) adjacent thereto. Since the III-V compound semiconductor of the semiconductor layer 27 has a photoluminescence wavelength value between the photoluminescence wavelength value exhibited by the SCH layer 23 or 25 and the photoluminescence wavelength value exhibited by the first or second semiconductor layer 3 and 7, the semiconductor layer 27 can decrease the mount of spikes and notches caused by the hetero-barrier between the SCH layer 23 or 25 and the first semiconductor layer 3 or the second semiconductor layer 7, thereby alleviating the hetero-barrier between the SCH layer 23 or 25 and the first and second semiconductor layer 3 or 7.

FIG. 5B is a chart showing the forbidden band width of the semiconductor light-emitting device taken along the line VI-VI of FIG. 5A, and illustrates the forbidden band widths of the first semiconductor layer 3, the active layer 5 of a single semiconductor film, the other semiconductor layer 27, the first SCH semiconductor layer 23, the second SCH semiconductor layer 25 and the second semiconductor layer 7. The structure of the semiconductor light-emitting device 1c can decrease the amount of spikes and notches caused by the hetero-barrier between the first SCH semiconductor layer 23 and the second semiconductor layer 7, and alleviates the hetero-barrier between the first SCH semiconductor layer 23 and the second semiconductor layer 7 as shown in FIG. 5B. Further, in the structure of the semiconductor light-emitting device 1c, the first and second SCH semiconductor layers 23 and 25 make it possible to confine current and light separately from each other.

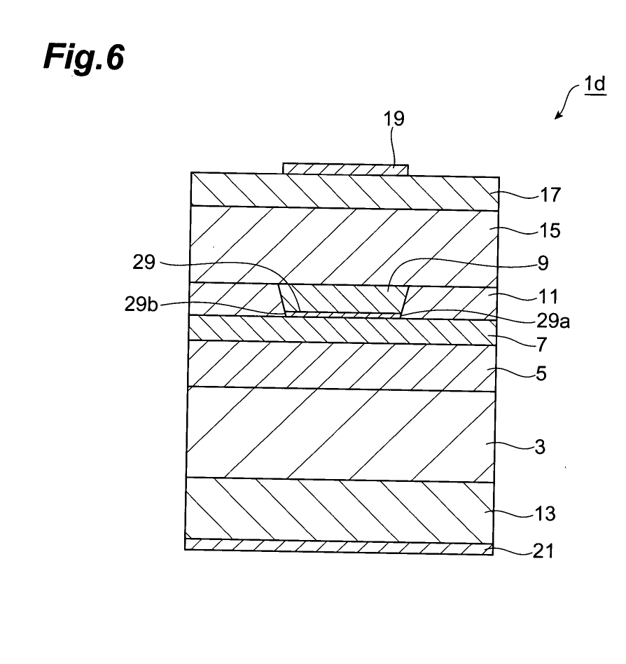

FIG. 6 is a sectional view showing the semiconductor light-emitting device in accordance with still another modified example of the first embodiment. The semiconductor light-emitting device 1d may further comprise an etching stop layer 29 in addition to the configuration of the semiconductor light-emitting device 1. The etching stop layer 29 is provided between the second semiconductor layer 7 and the third semiconductor layer 9. The etching stop layer 29 has the same conductivity type as the second semiconductor layer 7 and third semiconductor layer 9. The etching stop layer 29 serves to reduce fluctuations in the manufacturing of the ridge structure. The etching stop layer 29 may be provided between the second semiconductor layer 7 and the current block layer 11 as well.

In a first example of the semiconductor light-emitting device 1d,

the third semiconductor layer 9: p-type AlGaInP semiconductor and/or GaInP semiconductor; and

the semiconductor layer 29: p-type AlGaAs semiconductor, p-type GaAs semiconductor, and/or p-type GaInAsP semiconductor.

These materials for the etching stop layer exhibit an etching rate sufficiently lower than that of the third semiconductor layer 9 when using an etchant, such as hydrochloric acid.

In a second example of the semiconductor light-emitting device 1d,

the third semiconductor layer 9: p-type AlGaAs semiconductor; and

the semiconductor layer 29: p-type AlGaInP semiconductor, p-type GaInP semiconductor, and/or p-type GaInAsP semiconductor. These material for the etching stop layer exhibit an etching rate sufficiently lower than the third semiconductor layer 9 when using an etchant, such as phosphoric acid.

In the semiconductor optical device 1d, the etching stop layer 29 has a pair of side faces 29a and 29b, whereas the current block semiconductor layer 11 is provided on each of a pair of side faces 29a and 29b of the etching stop layer 29. For example, the current block semiconductor layer 11 is provide on both side of the etching stop layer 29.

This structure can change the effective refractive index of a semiconductor region, formed of the ridge semiconductor portions 9 and 29, to which current is injected. The effective refractive index depends on the refractive index of the etching stop layer.

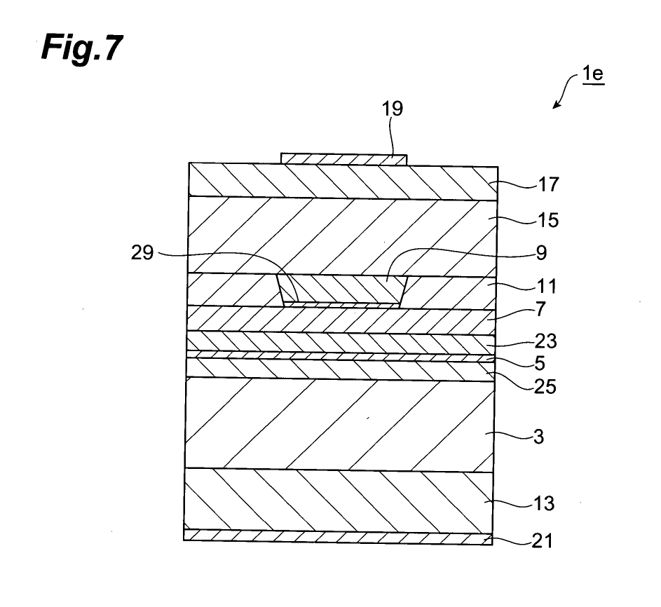

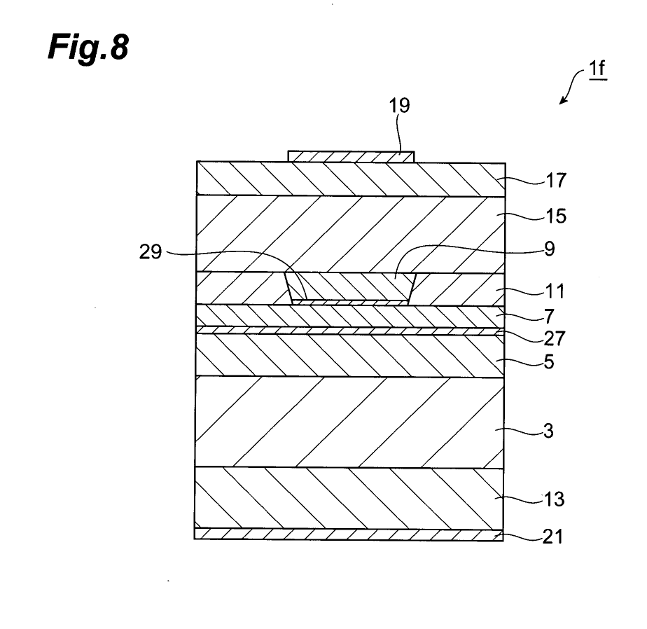

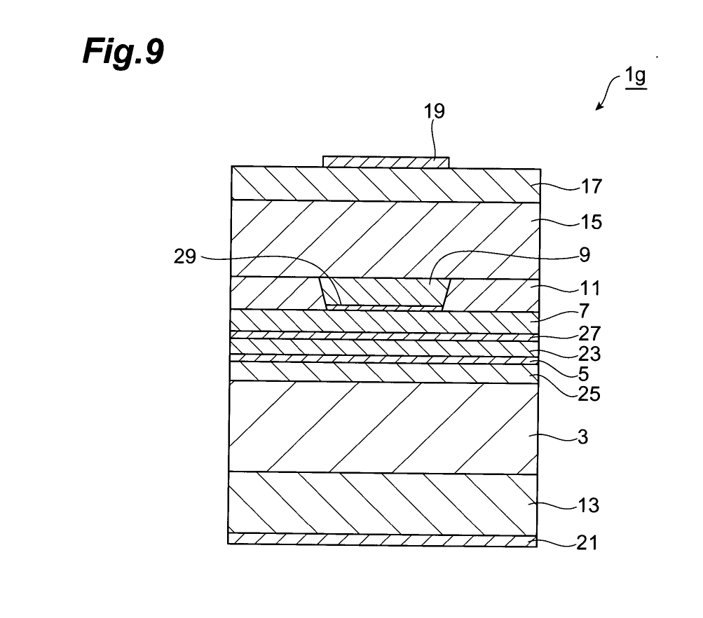

FIG. 7 is a sectional view showing the semiconductor light-emitting device in accordance with a modified example of the first embodiment. The semiconductor light-emitting device 1e may further comprise a first SCH semiconductor layer 23, a second SCH semiconductor layer 25, and an etching stop layer 29 in addition to the configuration of the semiconductor light-emitting device 1. FIG. 8 is a sectional view showing the semiconductor light-emitting device in accordance with a modified example of the first embodiment. The semiconductor light-emitting device 1f may further comprise a hetero-barrier alleviating layer 27 and an etching stop layer 29 in addition to the configuration of the semiconductor light-emitting device 1. FIG. 9 is a sectional view showing the semiconductor light-emitting device in accordance with a modified example of the first embodiment. The semiconductor light-emitting device 1g may further comprise SCH semiconductor layers 23 and 25, a hetero-barrier alleviating layer 27, and an etching stop layer 29 in addition to the configuration of the semiconductor light-emitting device 1. Modified examples of the first embodiment are not limited to the embodiments mentioned above. The SCH semiconductor layers, hetero-barrier alleviating layer, and etching stop layer may act in these modified examples as well.

As explained in the foregoing, the semiconductor light-emitting devices comprise an buried ridge structure, and have a refractive index guiding structure. In the refractive index guiding structure, a ridge semiconductor region through which injected current passes has an effective refractive index higher than that of a current block layer through which injected current does not pass. Such a semiconductor light-emitting device is useful for generating light having a wavelength of longer than 0.9 micrometers.

Second Embodiment

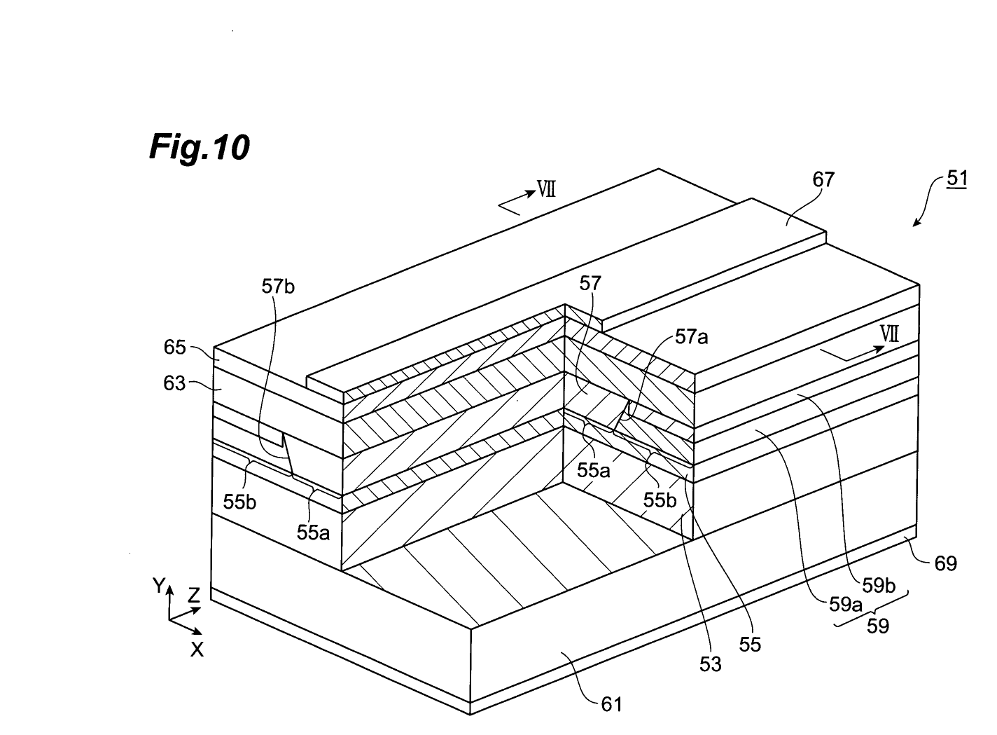

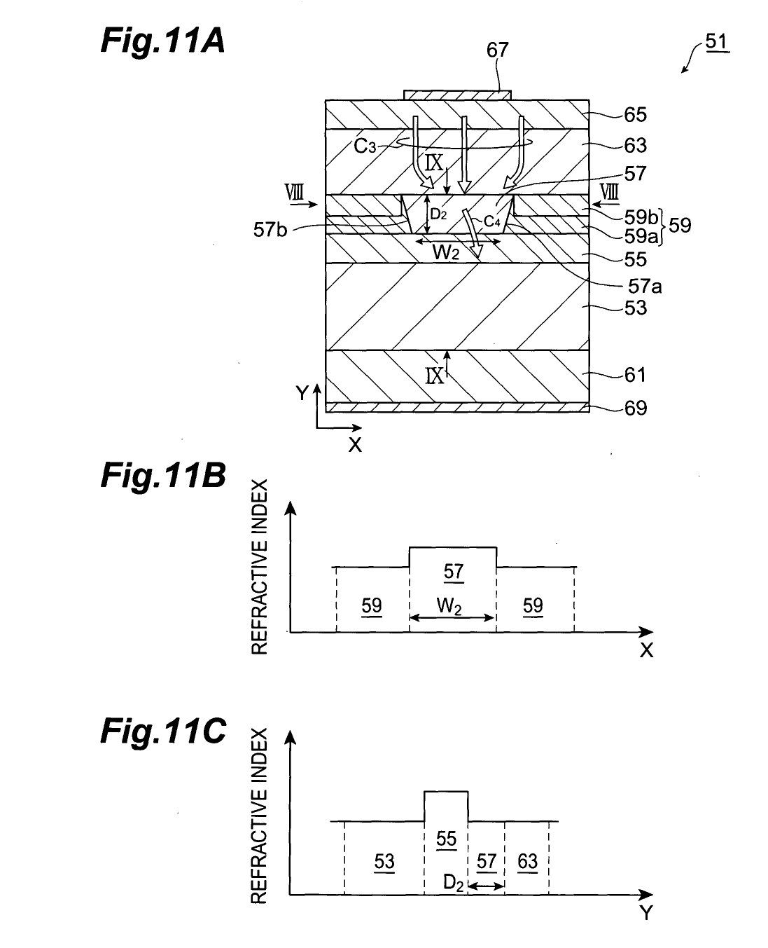

FIG. 10 is a perspective view showing the semiconductor light-emitting device in accordance with a second embodiment. FIG. 11A is a sectional view taken along the line VII-VII shown in FIG. 10. FIG. 11B is a chart showing the refractive index taken along the line VIII-VIII of FIG. 11A. Referring to FIGS. 10 and 11A, a semiconductor light-emitting device 51, such as buried ridge type semiconductor laser device, is shown.

The semiconductor optical device 51 comprises a first semiconductor layer 53 of a first conductivity type, an active layer 55, a second semiconductor layer 57 of a second conductivity type, and a current block semiconductor portion 59. The first semiconductor layer 53 is provided on a surface of a GaAs semiconductor portion. The active layer 55 is provided on the first semiconductor layer 53. The active layer 55 has a primary surface including a first area 55a and second areas 55b. The first area 55a and second areas 55b extend in a direction of a predetermined axis. The first area 55a is located between the second areas 55b. The second semiconductor layer 57 is provided on the first area 55a of the active layer 55, and has a pair of side faces 57a and 57b. The second semiconductor layer 57 extends in the direction of the predetermined axis, and has a stripe form. The current block semiconductor portion 59 is provided on the second areas 55b of the active layer 55. The current block semiconductor portion 59 has a first current block semiconductor layer 59a and a second current block semiconductor layer 59b. The first and second current block semiconductor layers 59a and 59b are provided on a pair of side faces 57a and 57b of the second semiconductor layer 57. The second semiconductor layer 57 has a refractive index higher than that of the first and second current block semiconductor layers 59a and 59b. The conductivity type of the first current block semiconductor layer 59a differs from that of the second current block semiconductor layer 59b.

The active layer 55 is formed of a III-V type compound semiconductor including at least nitrogen element as a V group member. Since the active layer 55 made of this III-V type compound semiconductor, including at least nitrogen element (N) as a V group member, is provided on a GaAs semiconductor surface, the semiconductor optical device 51 includes the current block semiconductor layer 59 and the second semiconductor layer 57 having a refractive index higher than that of the current block semiconductor layer 59. As shown in FIG. 11B, the refractive index of the second semiconductor layer 57 can be higher than that of the current block semiconductor layer 59. This configuration realizes a waveguide mode of a refractive index guiding type in the semiconductor optical device 51, thereby making it possible to enhance the confinement of lateral transverse modes. Consequently, the beam characteristics are stabilized, the optical coupling to an optical fiber is improved, and the threshold current is lowered in the semiconductor optical device 51.

FIG. 11C is a chart showing the refractive index taken along the line IX-IX of FIG. 11A. As shown in FIG. 1C, the active layer 55 has a refractive index higher than those of the first semiconductor layer 53, the second semiconductor layer 57 and current block semiconductor portion 59. The first semiconductor layer 53 has a first conductivity type and can work as a lower cladding layer. The second semiconductor layer 57 has a second conductivity type and can work as a first upper cladding layer. The active layer 55 generates light in response to the injection of carriers thereto. The first current block semiconductor layer 59a has the second conductivity type, whereas the second current block semiconductor layer 59b has the first conductivity type. The first current block semiconductor layer 59a is provided on the active layer 55. The second current block semiconductor layer 59b is provided on the first current block semiconductor layer 59a, and the second current block semiconductor layer 59b and the first current block semiconductor layer 59a forms a pn junction.

The semiconductor optical device 51 further comprises a third semiconductor layer 63 provided on the second semiconductor layer 57 and current block layer 59. The third semiconductor layer 63 has the second conductivity type and works as a second upper cladding layer. If the semiconductor layer 63 is used, the height of the ridge-shaped semiconductor portion is lowered. As the height D₂ of the ridge-shaped semiconductor portion is reduced, fluctuations in the width (referred to as Symbol W₂ in FIG. 11A) of the ridge-shaped semiconductor portion can be reduced in the manufacture of the semiconductor optical device. The refractive index of the semiconductor layer 63 is lower than that of the active layer 55. The third semiconductor layer 63 and the second current block semiconductor layer 59b form a pn junction.

The semiconductor light-emitting device 51 further comprises a substrate 61. The substrate 61 has a primary surface on which the first semiconductor layer 53, the active layer 55, the second semiconductor layer 57, the current block semiconductor layer 59 and the third semiconductor layer 63 are mounted. An example of the substrate 61 is a gallium arsenide substrate, but in the semiconductor optical device 51, the surface of GaAs semiconductor may be provided by a GaAs semiconductor layer provided on a substrate different from a gallium arsenide substrate, e.g., a silicon substrate.

The semiconductor optical device 51 may further comprise a contact layer 65 provided on the semiconductor layer 63, and an electrode 67 provided on the contact layer 65. The contact layer 65 has a carrier concentration higher than the semiconductor layer 63, and a forbidden band narrower than that of the semiconductor layer 63. Due to the higher carrier concentration and the narrower forbidden band, ohmic contact is realized between the contact layer 65 and the electrode 67. The rear face of the substrate 61 is provided with an electrode 69. One of the electrodes 67 and 69 acts as an anode, whereas the other acts as a cathode.

The electrode 67 has a stripe form extending in a direction of a predetermined axis, and is provided just above the ridge-shaped semiconductor layer 57. Therefore, carriers C₃ from the electrode 67 flow through the semiconductor layers 65 and 63. The carriers C₃ flow through the semiconductor layer 57, but not through the current block layer 59. That is, with the aid of the current block layer 59, the carriers C₃ flow into the semiconductor layer 57. Carriers from the electrode 67 are supplied to the active layer 55 only through the semiconductor layer 57 held by the current block portion 59. Therefore, the semiconductor optical device 51 mainly generates light in the active layer just below the ridge-shaped semiconductor layer 57.

In the semiconductor optical device 51, each of the first semiconductor layer 53, active layer 55, second semiconductor layer 57, current block semiconductor portion 59, semiconductor layer 63 and contact layer 65 is formed of a III-V compound semiconductor.

Each of the second semiconductor layer 57, third semiconductor layer 63, and current block semiconductor portion 59 maybe formed of an (Al_{X}Ga_{1-X})_{Y}In_{1-Y}P semiconductor (0≦X≦1) which lattice-matches to GaAs semiconductor. Alternatively, in the semiconductor optical device 51, each of the second semiconductor layer 57, third semiconductor layer 63, and current block semiconductor portion 59 may be formed of an Al_{X}Ga_{1-X}As semiconductor (0≦X≦1). If these semiconductor materials are used, the semiconductor optical device 51 may satisfy both of the requirement for the refractive index between the current block semiconductor portion and the cladding layers and the requirement for the carrier confinement between the active layer and the cladding layers.

In a first example of the semiconductor light-emitting device 51,

the first semiconductor layer 53: n-type AlGaInP semiconductor and/or GaInP semiconductor;

the active layer 55: un-GaInNAs semiconductor, un-GaNAs semiconductor, un-GaNAsSb semiconductor, un-GaNAsP semiconductor, un-GaNAsSbP semiconductor, un-GaInNAsSb semiconductor, un-GaInNAsP semiconductor, and/or un-GaInNAsSbP semiconductor;

the second semiconductor layer 57: p-type AlGaInP semiconductor and/or GaInP semiconductor;

the first current block semiconductor layer 59a: p-type AlGaInP semiconductor;

the second current block semiconductor layer 59b: n-type AlGaInP semiconductor;

the third semiconductor layer 63: p-type AlGaInP semiconductor and/or GaInP semiconductor;

the substrate 61: heavily doped n-type GaAs substrate; and

the contact layer 65: p-type GaAs semiconductor.

In a second example of the semiconductor light-emitting device 51,

the first semiconductor layer 53: n-type AlGaAs semiconductor;

the active layer 55: un-GaInNAs semiconductor, un-GaNAs semiconductor, un-GaNAsSb semiconductor, un-GaNAsP semiconductor, un-GaNAsSbP semiconductor, un-GaInNAsSb semiconductor, un-GaInNAsP semiconductor, and/or un-GaInNAsSbP semiconductor;

the second semiconductor layer 57: p-type AlGaAs semiconductor;

the first current block semiconductor layer 59a: p-type AlGaAs semiconductor;

the second current block semiconductor layer 59b: n-type AlGaAs semiconductor;

the third semiconductor layer 63: p-type AlGaAs semiconductor;

the substrate 61: heavily-doped n-type GaAs substrate; and

the contact layer 65: p-type GaAs semiconductor.

In these examples, the compositions of the second semiconductor layer 57 and current block semiconductor layer 59 are determined such that the second semiconductor layer 57 has a refractive index higher than that of the current block semiconductor portion 59. The first semiconductor layer 53, the second semiconductor layer 57, the third semiconductor layer 63, and the current block semiconductor layer 59 are formed of semiconductor materials which lattice-match to GaAs semiconductor. These semiconductor materials for the active layer may have the technical advantages described in the first embodiment as well.

As mentioned above, the III-V compound semiconductor for the active layer 55 of the semiconductor optical device 51 preferably includes at least gallium (Ga) as a III group member, and at least arsenic (As) and nitrogen (N) as V group members. If this III-V compound semiconductor is used for the active layer 55, the active layer 55 can be formed on the surface of GaAs semiconductor and thus the semiconductor optical device 51 can be formed from the current block semiconductor portion 59 and the second semiconductor layer 57 having a refractive index higher than that of the current block semiconductor portion 59. This structure of the semiconductor optical device 51 can realize the lateral transverse mode of a refractive index guiding type, whereby the semiconductor optical device 51 can enhance the confinement of the lateral transverse mode into the stripe region of the semiconductor optical device 51. Further, the active layer 55 may be formed from un-GaInAs semiconductor and/or un-GaInAsP semiconductor.

The materials for the active layer 55 as listed above have their technical effects identical to those described in the first embodiment. The active layer 55 of the semiconductor optical device 51 may have a quantum well structure as is the case with the first embodiment.

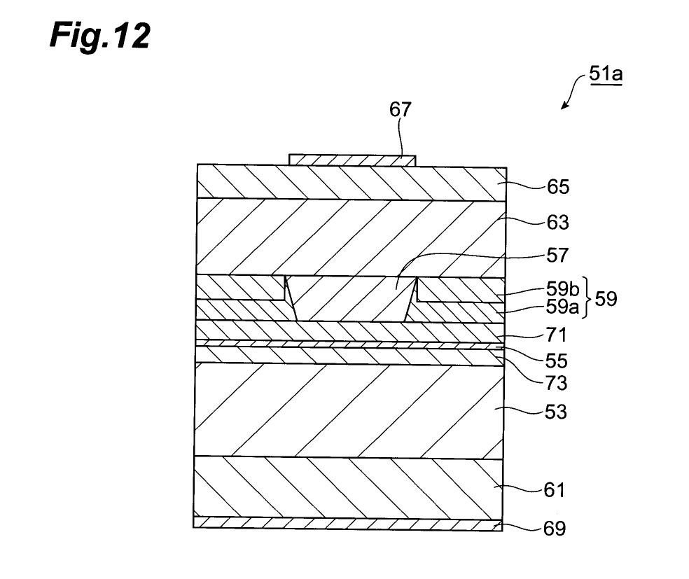

FIG. 12 is a sectional view showing the semiconductor light-emitting device in accordance with a modified example of the second embodiment. This semiconductor light-emitting device 51a has an SCH structure. The semiconductor optical device 51a may further comprise first and second SCH semiconductor layers 71 and 73 in addition to the configuration of the semiconductor light-emitting device 51. The first SCH semiconductor layer 71 is provided between the current block semiconductor portion 59 and second semiconductor layer 57 and the active layer 55. The second SCH semiconductor layer 73 is provided between the active layer 55 and the first semiconductor layer 53.

The relationship between forbidden band widths of the active layer 55 and the first and second SCH semiconductor layers 71, 73 is substantially the same as that shown in FIG. 3B. The relationship between refractive indices of the active layer 55 and the first and second SCH semiconductor layers 71, 73 is substantially the same as that shown in FIG. 3C. In the semiconductor light-emitting device 51a, carriers (electrons and holes) are confined in the active layer 55 with the aid of the first and second semiconductor layers 53 and 57 and the SCH semiconductor layers 71 and 73. In the semiconductor light-emitting device 51a, light is confined in the active layer 55 and the SCH semiconductor layers 71 and 73 with the aid of the first and second semiconductor layers 53 and 57 and the current block part 59. That is, the first and second SCH semiconductor layers 71 and 73 make it possible to confine current and light separately from each other.

In the semiconductor optical device 51a, each of the first SCH semiconductor layer 71 and second SCH semiconductor layer 73 may be formed of at least one of an Al_{X}Ga_{1-X}As semiconductor (0≦X≦1) and a GaInAsP semiconductor. If these materials are used, the refractive indices of the SCH semiconductor layers 71 and 73 can be set to values between those of the first semiconductor layer 53 and second semiconductor layer 57 and the active layer 55 to confine light within the active layer 55 and the SCH semiconductor layers 71 and 73, and the photoluminescence wavelength values of the SCH semiconductor layers 71 and 73 can be set to values between those of the first semiconductor layer 53 and second semiconductor layer 57 and the active layer 55 to confine carriers in the active layer 55.

In first and second examples of the semiconductor light-emitting device 51a,

the first and second SCH semiconductor layers 71 and 73: un-AlGaAs semiconductor, un-GaAs semiconductor, and/or un-Ga_{X}In_{1-X}As_{Y}P_{1-Y} semiconductor.

The GaInAsP semiconductor is formed so as to lattice-match to GaAs semiconductor.

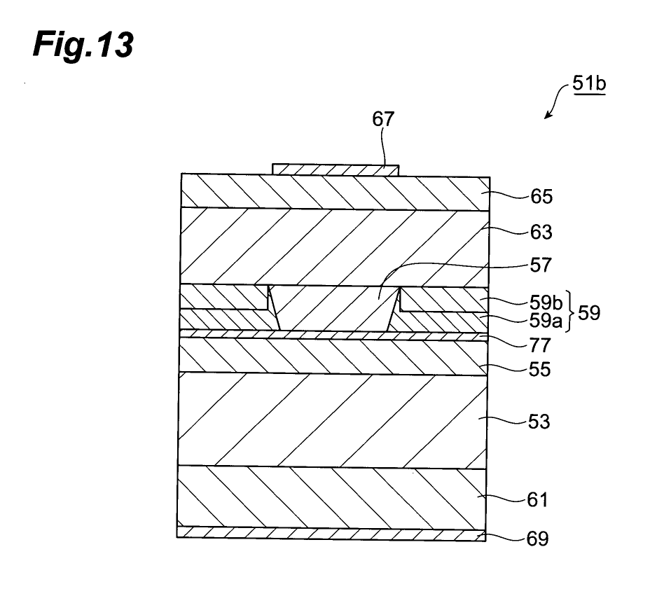

FIG. 13 is a sectional view showing the semiconductor light-emitting device in accordance with a modified example of the second embodiment. The semiconductor light-emitting device 51b may further comprise another semiconductor layer 77 to the configuration of the semiconductor light-emitting device 51. The other semiconductor layer 77 may be provided between the active layer 55 and the second semiconductor layer 57 or between the active layer 55 and the first semiconductor layer 53. The other semiconductor layer 77 is made of a III-V compound semiconductor.

This III-V compound semiconductor exhibits a photoluminescence wavelength value between the photoluminescence wavelength value exhibited by the active layer 55 and the photoluminescence wavelength value exhibited by the first semiconductor layer 53. If this relationship of photoluminescence wavelengths is satisfied, the other semiconductor layer 77 can decrease the amount of spikes or notches caused by the heterojunction between the active layer 55 and the first semiconductor layer 53 and can alleviate the hetero-barrier between the active layer 55 and the first semiconductor layer 53. This III-V compound semiconductor exhibits a photoluminescence wavelength value between the photoluminescence wavelength value exhibited by the active layer 55 and the photoluminescence wavelength value exhibited by the second semiconductor layer 57. If this relationship of photoluminescence wavelengths is satisfied, the other semiconductor layer 77 can decrease the amount of spikes or notches caused by the heterojunction between the active layer 55 and the second semiconductor layer 57, and can alleviate the hetero-barrier between the active layer 55 and the second semiconductor layer 57. The other semiconductor layer 77 acts as a hetero-barrier alleviating layer.

In first and second examples of the semiconductor light-emitting device 51b,

the semiconductor layer 77: p-type AlGaAs semiconductor, p-type AlGaInP semiconductor, p-type GaInP semiconductor, and/or p-type GaInAsP semiconductor.

If the semiconductor light-emitting device 51 comprises the hetero-barrier alleviating layer 77, the hetero-barrier alleviating layer 77 can reduce the electric resistance caused by spikes or notches at a heterojunction. In particular, if the heterojunction alleviating layer is provided in a p-type semiconductor region of the semiconductor light-emitting device 51, the electrical resistance from a large hetero-barrier against holes can be decreased. The hetero-barrier alleviating layer 77 can lower the amount of heat generated by the semiconductor light-emitting device, thereby improving device characteristics and long-term reliability. The hetero-barrier alleviating layer maybe, however, provided in an n-type semiconductor region of the semiconductor light-emitting device 51 as well.

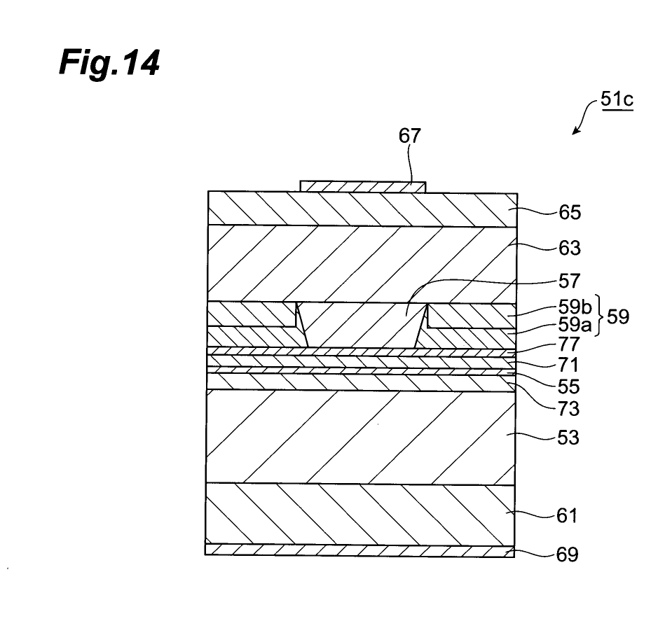

FIG. 14 is a sectional view showing the semiconductor light-emitting device in accordance with a modified example of the second embodiment. The semiconductor light-emitting device 51c may further comprise a first SCH semiconductor layer 71, a second SCH semiconductor layer 73, and another semiconductor layer 77 to the configuration of the semiconductor light-emitting device 51. The structure of the semiconductor light-emitting device Sic restrains spikes or notches caused by the heterojunction between the first SCH layer 71 and the second semiconductor layer 57, and alleviates the hetero-barrier between the first SCH layer 71 and the second semiconductor layer 57. In the structure of the semiconductor light-emitting device 51c, the first and second SCH semiconductor layers 71 and 73 make it possible to confine current and light separately from each other.

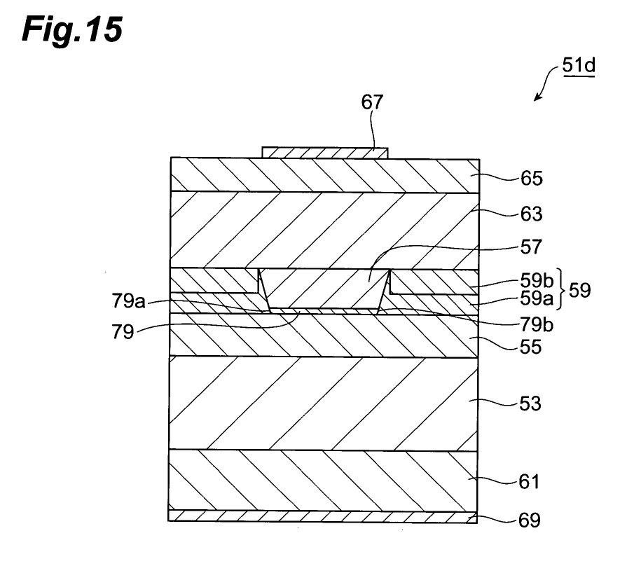

FIG. 15 is a sectional view showing the semiconductor light-emitting device in accordance with a modified example of the second embodiment. The semiconductor light-emitting device 51d may further comprise an etching stop layer 79 in addition to the configuration of the semiconductor light-emitting device 51. The etching stop layer 79 is provided between the second semiconductor layer 57 and the active layer 55. The etching stop layer 79 serves to reduce fluctuations in the ridge structure in the manufacture of the semiconductor light-emitting device 51. The etching stop layer 79 may be provided between the active layer 55 and the current block layer 59 as well.

In a first example of the semiconductor light-emitting device 51d,

the second semiconductor layer 57: p-type AlGaInP semiconductor and/or GaInP semiconductor; and

the semiconductor layer 79: p-type AlGaAs semiconductor, p-type GaAs semiconductor, and/or p-type GaInAsP semiconductor.

These materials for the etching stop layers 79 exhibit an etching rate sufficiently lower than that of the second semiconductor layer 57 when using an etchant, such as hydrochloric acid.

In a second example of the semiconductor light-emitting device 51d,

the second semiconductor layer 57: p-type AlGaAs semiconductor; and

the semiconductor layer 79: p-type AlGaInP semiconductor, p-type GaInP semiconductor, and/or p-type GaInAsP semiconductor.

These materials for the etching stop layers 79 exhibit an etching rate sufficiently lower than that of the second semiconductor layer 57 when using an etchant, such as a phosphoric acid.

In the semiconductor optical device 51d, the etching stop layer 79 has a pair of side faces 79a and 79b, whereas the current block semiconductor portion 59 is provided on each of a pair of side faces 79a and 79b of the etching stop layer 79. For example, the current block semiconductor layer 59 is provided on the side faces 79a and 79b of the etching stop layer 79.

This structure can change the effective refractive index of a current injection region, formed from the ridge semiconductor portions 57 and 79, by changing the refractive index of the etching stop layer.

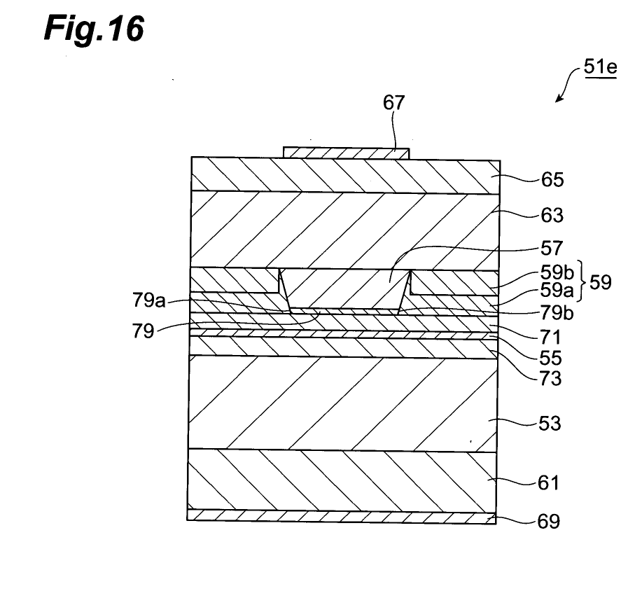

Modified examples of the semiconductor light-emitting device in the second embodiment are not limited to the examples mentioned above. As shown in FIG. 16, the semiconductor light-emitting device 51e may comprise a first SCH semiconductor layer 71, a second SCH semiconductor layer 73, and an etching stop layer 79. There are other modified examples of the semiconductor light-emitting device, such as a semiconductor light-emitting device further comprising a hetero-barrier alleviating layer and an etching stop layer; and a semiconductor light-emitting device further comprising an SCH structure, a hetero-barrier alleviating layer and an etching stop layer.

The semiconductor light-emitting devices explained in the foregoing have buried ridge structures and refractive index guiding structures. In refractive index guiding structures, the ridge semiconductor portion into which current is injected has an effective refractive index higher than that of a current block layer into which current does not flow.

Since the first current block semiconductor layer 59a can be formed from a semiconductor material different from the semiconductor material of the second semiconductor layer 57, the controllabilities of the carrier confinement and the lateral transverse modes are enhanced in the semiconductor light-emitting device in accordance with the second embodiment as compared to the semiconductor light-emitting device in accordance with the first embodiment.

In the semiconductor light-emitting device of the second embodiment, the first current block semiconductor layer 59a can be made of material having a bandgap greater than that of the second semiconductor layer 57 to increase the hetero-barrier between the current block portion 59 and the second semiconductor layer 57. Therefore, the semiconductor light-emitting device in accordance with the second embodiment can enhance the confinement of carriers into the current injection region to reduce the inactive current that does not contribute to light emission in the semiconductor light-emitting device.

As explained in the foregoing, the semiconductor light-emitting device of the second embodiment can enhance the confinement of carriers into the current injecting region.

In the first and second embodiments, a semiconductor optical amplifier is provided by forming a coating film of lowering reflectivity on each facet of the semiconductor optical amplifier to avoid its laser oscillation. In the semiconductor optical devices of the first and second embodiments, in order to achieve the excellent performance of the semiconductor optical amplifier, the reflectivity of each facet should be not more than 0.1 percent to suppress Fabry-Perot modes in the semiconductor optical amplifier. A single-layer dielectric film, such as SiN, SiO₂ and Al₂O₃ can be used as a low reflectivity coating film. Alternatively, a multilayer dielectric film in which a low reflectivity film, such as SiN, SiO₂ and Al₂O₃, and high reflectivity film, such as TiO₂ and a-Si, are deposited alternately can be used for the low reflectivity coating film. The allowable ranges of thickness and refractive index of the coating film to obtain a required reflectivity are broader in the multilayer film compared with the single layer film. In addition, the wavelength range within which the device can act as a semiconductor optical amplifier is broader in the multilayer film compared with the single layer film. Therefore, the multilayer coating film is more suitable than the single layer coating film for the fabrication of the semiconductor optical amplifier. Because the semiconductor optical amplifier of the present invention can include a cladding layer of an (Al_{X}Ga_{1-X})_{Y}In_{1-Y}P (0≦X≦1) semiconductor or Al_{X}Ga_{1-X}As (0≦X≦1) semiconductor having a larger bandgap, the bandgap difference between the active layer and the cladding layer is increased. Accordingly, the confinement of carriers into the active layer can be enhanced to improve the temperature characteristics of the semiconductor optical amplifier. In the semiconductor optical amplifier, the lateral transverse mode becomes a refractive index guiding mode due to the reason described in the first and second embodiments. Consequently, the semiconductor optical amplifier confines light strongly in the stripe region to enhance the efficiency of stimulated emission, thereby achieving excellent amplification characteristics.

From the viewpoint of semiconductor material, a III-V compound semiconductor including nitrogen (N) may be used for the active layer as explained above. The III-V compound semiconductor including nitrogen may be, for example, III-V compound semiconductors including at least nitrogen, gallium and arsenic. These semiconductors have lattice constants equal or close to that of GaAs semiconductor. Therefore, the above semiconductors can be grown on the GaAs semiconductor surface with a good crystalline quality. In addition, a long-wavelength semiconductor light-emitting device is made of these semiconductor materials having a bandgap value corresponding to an oscillation wavelength region of longer than 0.9 micrometers, such that the semiconductor light-emitting device can generate light of a wavelength of longer than 0.9 micrometers.

In the semiconductor light-emitting devices of the first and second embodiments, semiconductor layers working as cladding layers may be formed of an (Al_{X}Ga_{1-X})_{Y}In_{1-Y}P semiconductor (0≦X≦1) or an Al_{X}Ga_{1-X}As semiconductor (0≦X≦1). Using these materials can improve the carrier confinement. On the other hand, among the semiconductor materials in InP/InGaAsP long-wavelength semiconductor laser devices, InP semiconductor has the largest bandgap. But the bandgap value of InP semiconductor is only 2.16×10⁻¹⁹ joules (1.35 eV). Therefore, even if a cladding layer is made of an InP semiconductor in this semiconductor laser device, the bandgap difference between the cladding layer and the active layer is not large, which results in a poor carrier confinement in the active layer.

The bandgap of the (Al_{X}Ga_{1-X})_{Y}In_{1-Y}P semiconductor (0≦X≦1) varies within the range of 3.06×10⁻¹⁹ joules (1.91 eV) to 3.92×10⁻¹⁹ joules (2.45 eV) depending on the composition X of Al. The bandgap of the Al_{X}Ga_{1-X}As semiconductor (0≦X≦1) varies within the range of 2.27×10⁻¹⁹ joules (1.42 eV) to 3.19×10⁻¹⁹ joules (1.99 eV) depending on the composition X of Al. Accordingly, the latter can yield a greater bandgap difference between the cladding layer and the active layer as compared with the InP semiconductor. Hence, it can enhance the confinement of carriers into the active layer, thereby improving the temperature characteristic of the semiconductor light-emitting device.

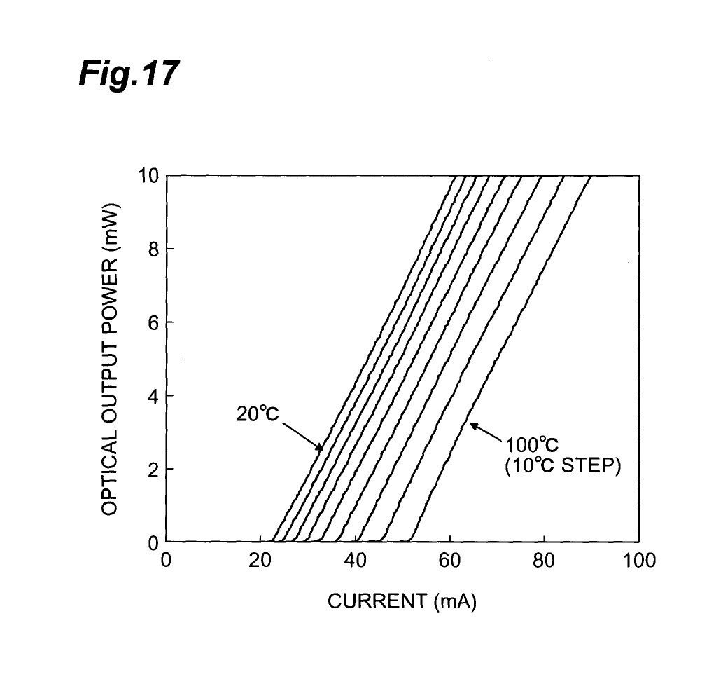

FIGS. 17, 18 and 19 show temperature characteristics of a GaInNAs laser having the following semiconductor layers:

the cladding layers 3, 7, 9, 15: GaInP the active layer 5: GaInNAs;

the SCH layers 23, 35: GaAs;

the hetero-barrier alleviating layer 27: GaInAsP;

the etch stop layer 29: GaInAsP;

the current block semiconductor layers 11: AlGaInP.

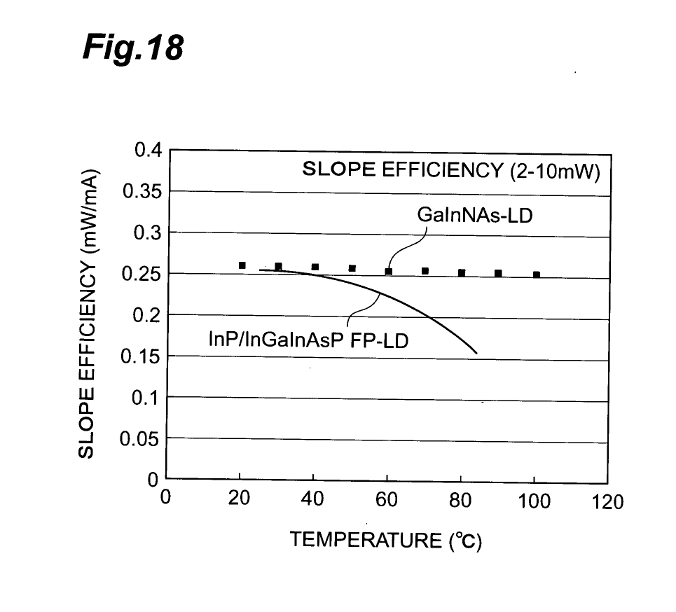

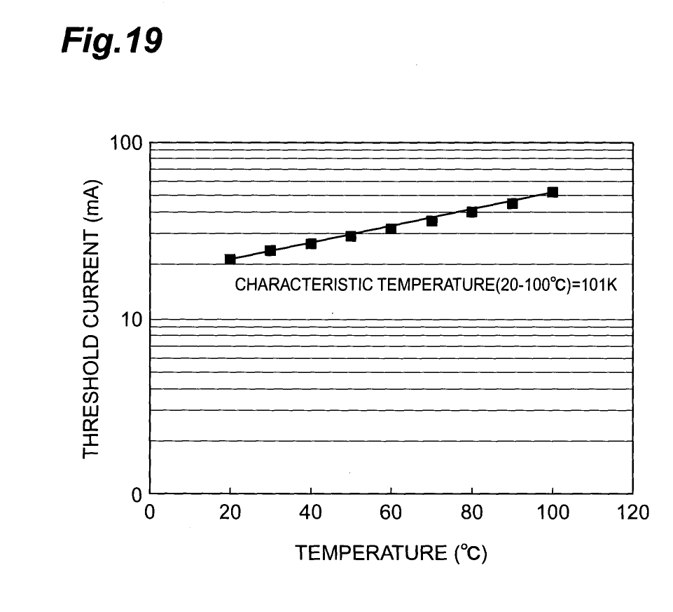

The cavity length of this GaInNAs laser is 600 micrometers. FIG. 17 shows the current versus optical output characteristics of the GaInNAs laser. As shown in FIG. 17, the GaInNAs laser exhibits an excellent linearity in the current versus optical output characteristics in the range of 20 to 100 degrees Celsius without the degradation of slope efficiency. The GaInNAs laser can generate optical output power more than 10 milliwatts at 100 degrees Celsius. FIG. 18 shows the comparison in the temperature dependence of slope efficiency between an InP/InGaAsP laser and the GaInNAs laser. As shown in FIG. 18, the slope efficiency of the GaInNAs laser exhibits little temperature dependence, whereas the slope efficiency of the InP/GaInNAs laser decreases with temperature. The comparison between these lasers reveals that the temperature characteristics of the slope efficiency is much improved in the GaInNAs laser. FIG. 19 shows the temperature dependence of threshold current of the GaInNAs laser. As shown in FIG. 19, the GaInNAs laser has the characteristic temperature of 101 degrees Celsius, whereas conventional InP/InGaAsP lasers have characteristic temperatures of, at most, 70 degrees Celsius or so. Therefore, it is clear that the temperature dependence of the threshold current is also lowered in the GaInNAs laser. The experimental results in FIGS. 17, 18 and 19 reveal that the structure of the semiconductor laser according to the present embodiments improves its temperature characteristics.

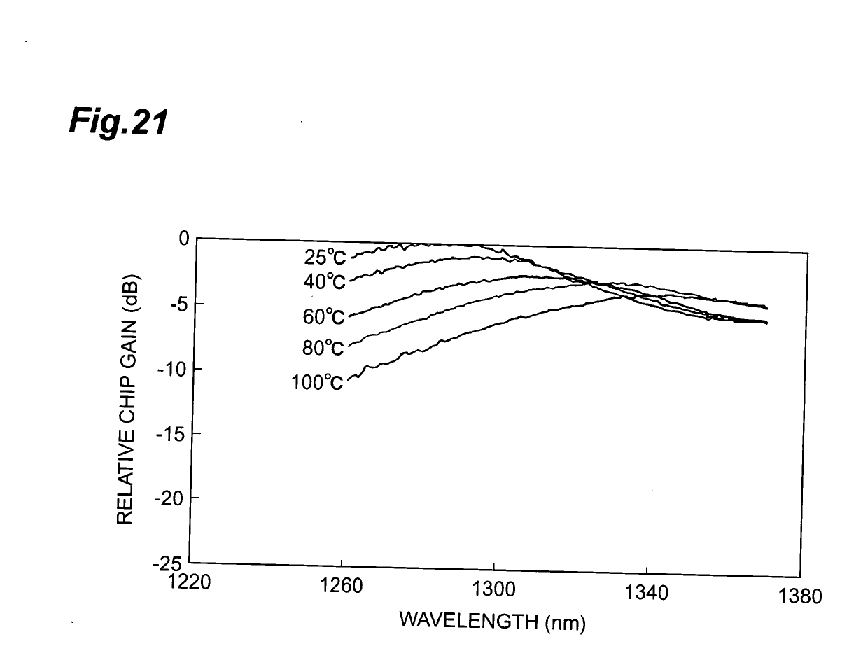

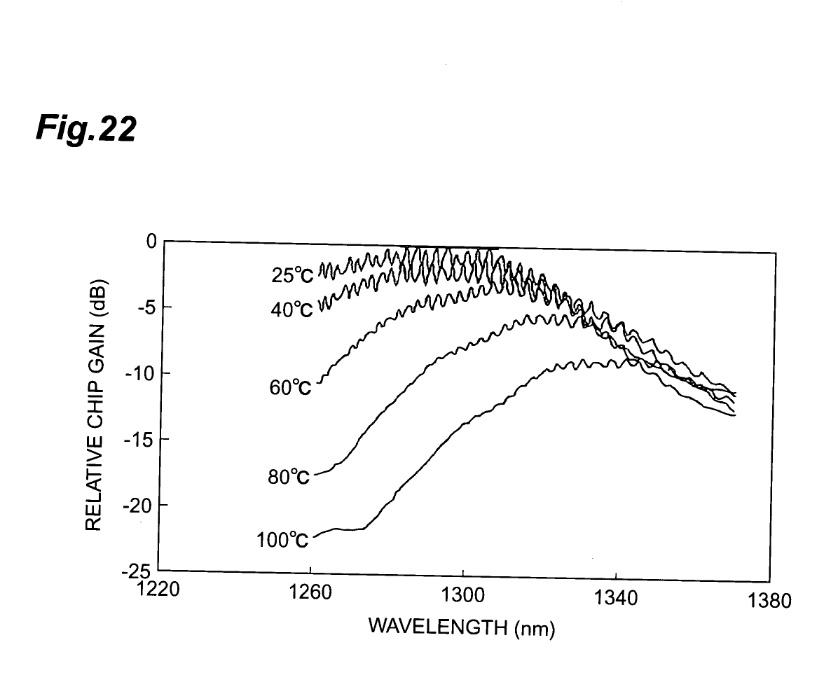

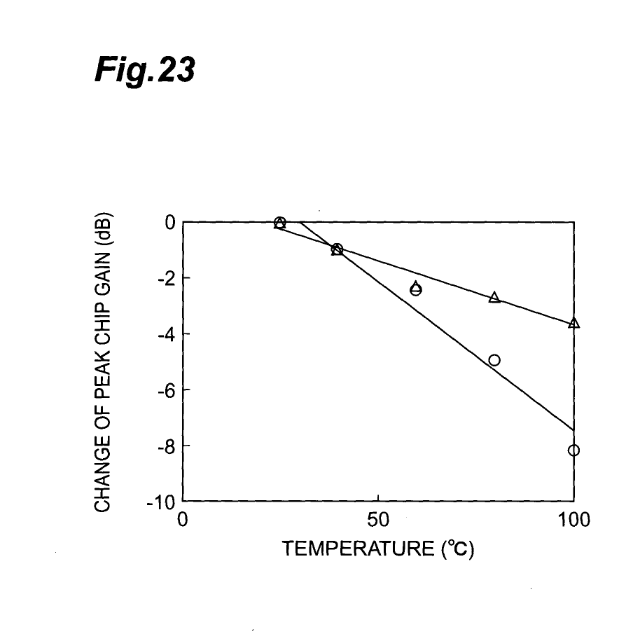

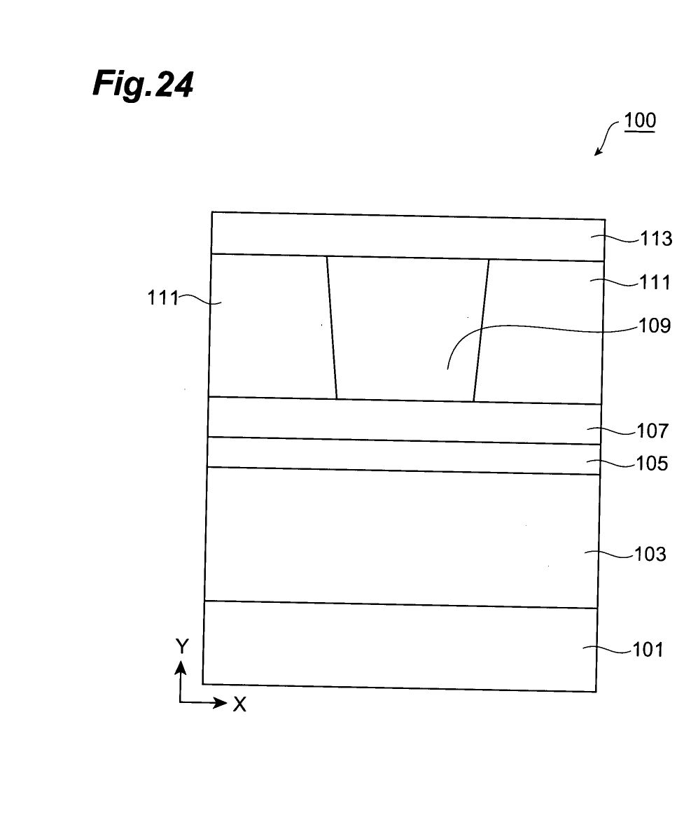

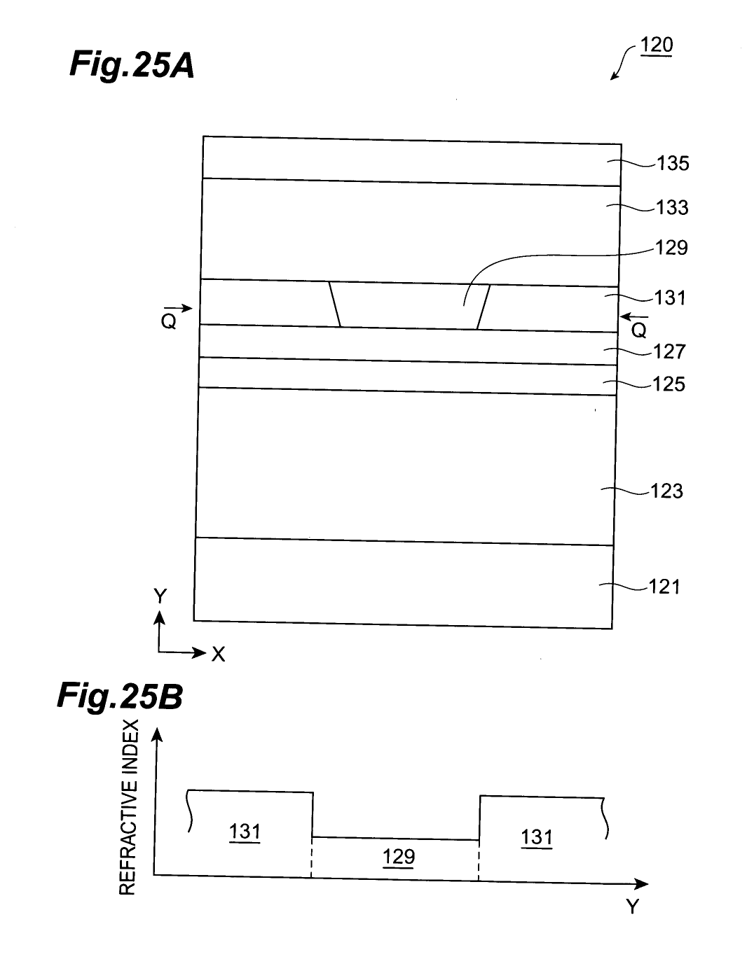

In a semiconductor laser which has the same structure as described in the just above paragraph, a coating film is formed on each facet thereof to obtain an optical semiconductor amplifier (referred to as a “GaInNAs optical amplifier”). FIG. 21 shows the temperature dependence of chip gain of the GaInNAs optical amplifier, in which the reflectivity of the coating film is 0.1 percent or lower. In FIG. 21, the ordinate axis indicates relative values of chip gain, and the abscissas axis indicates the wavelength of amplified light. FIG. 22 shows the temperature dependence of chip gain of an InP/InGaAsP semiconductor optical amplifier. The GaInNAs optical amplifier generates light in the 1.3 micrometer band which is the same as the InP/InGaAsP semiconductor optical amplifier. The cavity length of the GaInNAs optical amplifier is 300 micrometers which is the same as the InP/InGaAsP semiconductor optical amplifier. Current injected to the GaInNAs optical amplifier is 40 microamperes which is the same as the InP/InGaAsP semiconductor optical amplifier. The comparison reveals that the GaInNAs optical amplifier exhibits the temperature dependence of chip gain much smaller than that of the InP/InGaAsP semiconductor optical amplifier. FIG. 23 shows the temperature dependence of peak chip gain, derived from the results in FIGS. 21 and 22, of the GaInNAs optical amplifier and InP/InGaAsP semiconductor optical amplifier. In FIG. 23, the ordinate axis indicates the decrease measured from the value at 25 degrees Celsius, and the abscissas axis indicates the device temperature. Symbol “Δ” indicates data from the GaInNAs optical amplifier, and symbol “◯” indicates data from the InP/InGaAsP semiconductor optical amplifier. FIG. 23 shows that the decreasing rate of peak chip gain of the GaInNAs optical amplifier is −0.045 dB per Kelvin and that the decreasing rate of peak chip gain of the InP/InGaAsP semiconductor optical amplifier is −0.11 dB per Kelvin. The decreasing rate of the former is much smaller than that of the latter. The several measurement data shown above demonstrate that the semiconductor optical amplifier having the structures as described in the specification can improve the temperature characteristics of the optical amplifier.

As the Al composition increases in the Al_{X}Ga_{1-X}As semiconductor (0≦X≦1) and in the (Al_{X}Ga_{1-X})_{Y}In_{1-Y}P semiconductor (0≦X≦1) lattice-matching to GaAs semiconductor, their bandgaps increase and their refractive indexes decrease. The refractive index of the cladding layer becomes higher than that of a current block layer if a semiconductor having a relatively smaller Al composition and a semiconductor having a relatively larger Al composition are used for the cladding layer and the current block layer, respectively. Therefore, the effective refractive index within a semiconductor stripe located between current block semiconductor regions can be made higher than that of the current block semiconductor regions. This structure provides a refractive index guiding in a lateral transverse direction, and the confinement of light in the transverse direction can be enhanced, so that a low threshold can be realized in the semiconductor laser device. Since the confinement of light in the transverse direction becomes stable, the semiconductor laser device can oscillate with single and fundamental mode, thereby improving the optical coupling of the semiconductor laser device with an optical fiber. The semiconductor laser device according to this embodiment of the present invention can greatly improve semiconductor laser characteristics as compared with InP buried ridge type laser devices.

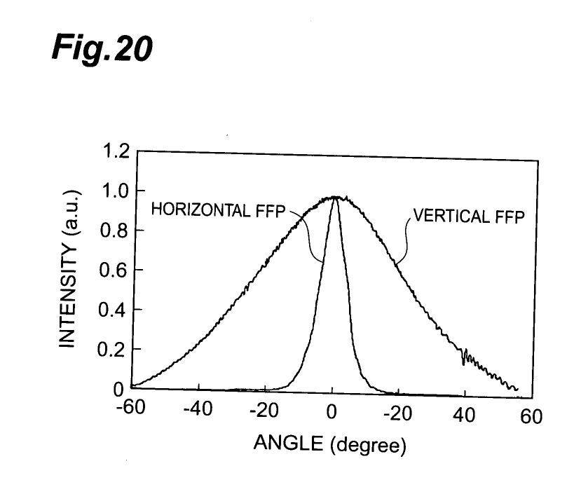

FIG. 20 shows the Far Field Pattern of the above GaInNAs laser. The Far Field Pattern in the horizontal direction exhibits a single-peaked pattern of an axial symmetry. This pattern demonstrates that a fundamental and normal waveguide mode propagates in the lateral transverse direction. In the GaInNAs laser, the semiconductor stripe formed of semiconductor material having a refractive index greater than that of the current block layers forms a refractive index guiding structure because of the following: the current block portion 11 is formed of an AlGaInP semiconductor so that the Al content of the current block portion 11 is increased as compared to the second upper cladding layer 9 made of a GaInP semiconductor; the etching stop layer 29 is formed of GaInAsP exhibiting a large refractive index. This refractive index guiding structure can enhance the confinement of light, so that the GaInNAs laser has a low threshold current of 20 or slightly more milliamperes at room temperature even when the laser has a longer cavity of 600 micrometers or so. Since the confinement of light is stabilized in the transverse direction due to the refractive index guiding structure, the stable oscillation of the fundamental lateral transverse mode is achieved.

When materials of cladding layers are the Al_{X}Ga_{1-X}As semiconductor (0≦X≦1) and/or the (Al_{X}Ga_{1-X})_{Y}In_{1-Y}P semiconductor (0≦X≦1) lattice-matching to GaAs semiconductor, an SCH semiconductor layer can be made of Al_{X}Ga_{1-X}As semiconductor (0≦X≦1) or a Ga_{X}In_{1-X}As_{Y}P_{1-Y} semiconductor (about 0.5≦X≦1, 0≦Y≦1) lattice-matching to GaAs. Using the SCH semiconductor layer can enhance the confinement of light into the active layer, thereby resulting in low threshold current, excellent temperature characteristics, and improved oscillation characteristics. The SCH semiconductor layer works remarkably if the active layer has a quantum well structure.

In the second embodiment, the hetero-barrier alleviating layer may be formed not under the current block layer, but only under the second semiconductor layer. This structure can change the effective refractive index of the stripe region depending on the refractive index of a hetero-barrier alleviating layer. For example, even when the current block layer is not made of material exhibiting a refractive index lower than that of the cladding layer, a normal waveguide structure can be still obtained by using a hetero-barrier alleviating layer that exhibits a high refractive index.

The hetero-barrier alleviating layer may have a composition in which the lattice mismatch is between −2 percent and 2 percent with respect to a semiconductor substrate. In general, the thickness of a hetero-barrier alleviating layer is smaller than the critical film thickness. For example, the film thickness of the hetero-barrier alleviating layer is between 5 nanometers and 10 nanometers, and is preferably 5 nanometers. In this range, there is little occurrence of crystal defects due to the lattice mismatch. Since the constraint on lattice mismatch is alleviated, the scope of choices available for semiconductor materials expands in the device. If the cladding layer material is an Al_{X}Ga_{1-X}As semiconductor (0≦X≦1) and/or (Al_{X}Ga_{1-X})_{Y}In_{1-Y}P semiconductor (0≦X≦1) lattice-matching to GaAs semiconductor and the SCH semiconductor layer material is Al_{X}Ga_{1-X}As semiconductor (0≦X≦1) and/or Ga_{X}In_{1-X}As_{Y}P_{1-Y} semiconductor (about 0.5≦X≦1, 0≦Y≦1) lattice-matching to GaAs, (Al_{X}Ga_{1-X})_{Y}In_{1-Y}P and Ga_{X}In_{1-X}As_{Y}P_{1-Y} semiconductors can be used for a strained hetero-barrier alleviating layer.

If an etching stop layer in the buried ridge type semiconductor light-emitting device of the first embodiment is used, it is easy to control the thickness of the second semiconductor layer and the ridge width of the third semiconductor layer, which play an important role in the confinement of lateral transverse mode, the single mode operation of lateral transverse mode, and oscillation characteristics. If the material of the cladding layer is an (Al_{X}Ga_{1-X})_{Y}In_{1-Y}P semiconductor (0≦X≦1) lattice-matching to GaAs semiconductor, an etching stop layer can be made of Al_{X}Ga_{1-X}As semiconductor (0≦X≦1) and Ga_{X}In_{1-X}As_{Y}P_{1-Y} semiconductor, for example. If the cladding layer material is an Al_{X}Ga_{1-X}As semiconductor (0≦X≦1), an etching stop layer can be made of (Al_{X}Ga_{1-X})_{Y}In_{1-Y}P semiconductor (0≦X≦1) lattice-matching to GaAs semiconductor, for example.

The etching stop layer may be provided only within the ridge semiconductor portion. In this structure, the effective refractive index of the stripe region can be changed depending on the refractive index of the etching stop layer. For example, even when the current block layer is not made of material exhibiting a refractive index lower than that of the cladding layer, a normal waveguide structure can be still obtained by using the etching stop layer made of material exhibiting a high refractive index.

The composition of the etching stop layer may be within a range in which the lattice mismatch is between −2 percent and +2 percent with respect to a semiconductor substrate. In general, the thickness of the hetero-barrier alleviating layer is smaller than its critical film thickness. For example, the thickness of the etching stop layer is between 5 nanometers and 10 nanometers, and is preferably 5 nanometers. There is little occurrence of crystal defects due to lattice mismatch in this range. Since the constraint on lattice mismatch is alleviated, the scope of choices available for semiconductor materials for the device expands. If material for the cladding layer is an (Al_{X}Ga_{1-X})_{Y}In_{1-Y}P semiconductor (0≦X≦1) lattice-matching to GaAs semiconductor, a strained etching stop layer can be formed of Ga_{X}In_{1-X}As_{Y}P_{1-Y} semiconductors, for example. If material for the cladding layer is an Al_{X}Ga_{1-X}As semiconductor (0≦X≦1), a strained etching stop layer can be form of (Al_{X}Ga_{1-X})_{Y}In_{1-Y}P semiconductors and/or Ga_{X}In_{1-X}As_{Y}P_{1-Y} semiconductors, for example.

The bandgap of the etching stop layer may be substantially the same as that of at least one of cladding layers. This structure can lower increase the resistance caused by the etching stop layer.

In the first and second embodiments, the active layer may have a strained quantum well structure. The strained quantum well structure may include at least one of a GaInAs semiconductor and a GaInAsP semiconductor. The light-emitting device having this strained quantum well structure can generate light having a wavelength of longer than 0.9 micrometers.

As explained in the foregoing, the semiconductor light-emitting device according to the embodiments of the present invention can be utilized in a 0.98-micrometer band pumping semiconductor laser device for an erbium-doped optical fiber amplifier and in a 1.017-micrometer band pumping semiconductor laser device for a praseodymium-doped optical fiber amplifier. A compressive strained GaInAs semiconductor layer improves laser oscillation conditions of a GaInAs semiconductor laser device, such as threshold gain, thereby realizing high-output characteristics in the GaInAs semiconductor laser device. The strained quantum well structure of GaInAsP semiconductor improves laser oscillation conditions, such as threshold gain, and the amount of strain in this strained quantum well structure can be widely changed as compared to the GaInAs semiconductor because the number of constituent elements of GaInAsP semiconductor is greater than that of GaInAS semiconductor. Accordingly, the degree of freedom in the design of the semiconductor laser device can further be enhanced.

The semiconductor light-emitting devices in accordance with the first and second embodiments can provide a solution of the problem in terms of high-temperature characteristics of InGaAsP/InP semiconductor laser devices. The semiconductor light-emitting devices in accordance with the first and second embodiments can provide a solution of the problem in term of semiconductor optical waveguides of an anti refractive index guiding structure in buried ridge type semiconductor laser devices.

As explained in the foregoing, the present invention provides a semiconductor optical device which can enhance the confinement of transverse modes.

Having described and illustrated the principle of the invention in a preferred embodiment thereof, it is appreciated by those having skill in the art that the invention can be modified in arrangement and detail without departing from such principles. For example, the semiconductor optical device encompasses not only semiconductor light-emitting devices, but also semiconductor laser devices, semiconductor optical amplifier devices, semiconductor optical integrated devices including EA modulators, and the like, as well as integrated devices integrating these devices. Details of structures of these devices can be modified as necessary. We therefore claim all modifications and variations coming within the spirit and scope of the following claims.

What is claimed is:

1. A semiconductor optical device comprising:
a first semiconductor layer of a first conductivity type provided on a surface of GaAs semiconductor;
an active layer provided on said first semiconductor layer;
a second semiconductor layer of a second conductivity type provided on said active layer, said second semiconductor layer having a primary surface, said primary surface having a first area and second areas, said first area being provided between said second areas;
a third semiconductor layer of said second conductivity type provided on said first area of said second semiconductor layer; and
a current block semiconductor portion of said first conductive type provided on said second areas of said second semiconductor layer;
wherein a refractive index of said third semiconductor layer is higher than that of said current block semiconductor portion; and
wherein said active layer is constituted by a III-V compound semiconductor containing at least a nitrogen element as a V group member.

2. The semiconductor optical device according to claim 1, further comprising a fourth semiconductor layer including a III-V compound semiconductor, said fourth semiconductor layer being provided between said active layer and at least one of said first and said second semiconductor layers;
wherein said III-V compound semiconductor exhibits a photoluminescence wavelength value between a photoluminescence wavelength value exhibited by said active layer and a photoluminescence wavelength value exhibited by one of said first and said second semiconductor layers.

3. The semiconductor optical device according to claim 1, further comprising a first SCH semiconductor layer provided between said second semiconductor layer and said active layer; and
a second SCH semiconductor layer provided between said active layer and said first semiconductor layer.

4. The semiconductor optical device according to claim 3, further comprising a fourth semiconductor layer including a III-V compound semiconductor, said fourth semiconductor layer being provided between said second SCH semiconductor layer and said first semiconductor layer;
wherein said III-V compound semiconductor of said fourth semiconductor layer exhibits a photoluminescence wavelength value between a photoluminescence wavelength value exhibited by said second SCH layers and a photoluminescence wavelength value exhibited by said first semiconductor layer.

5. The semiconductor optical device according to claim 3, further comprising a fourth semiconductor layer including a III-V compound semiconductor, said fourth semiconductor layer being provided between said first SCH semiconductor layer and said second semiconductor layer;
wherein said III-V compound semiconductor of said fourth semiconductor layer exhibits a photoluminescence wavelength value between a photoluminescence wavelength value exhibited by said first SCH layer and a photoluminescence wavelength value exhibited by said first semiconductor layer.

6. The semiconductor optical device according to claim 1, further comprising an etching stop layer provided between said second and said third semiconductor layers.

7. The semiconductor optical device according to claim 6, wherein said etching stop layer has a pair of side faces;
wherein said current block semiconductor portion is provided on each side face of said etching stop layer.

8. The semiconductor optical device according to claim 1, further comprising a fifth semiconductor layer and a contact layer, said fifth semiconductor layer being provided on said third semiconductor layer and said current block semiconductor portion, and said contact layer being provided on said fifth semiconductor layer.

9. The semiconductor optical device according to claim 1, wherein each of said second and said third semiconductor layers and said current block semiconductor portion is constituted by an (Al_{X}Ga_{1-X})_{Y}In_{1-Y}P semiconductor (0≦X≦1).

10. The semiconductor optical device according to claim 1, wherein each of said second and said third semiconductor layers and said current block semiconductor portion is constituted by an Al_{X}Ga_{1-X}As semiconductor (0≦X≦1).

11. The semiconductor optical device according to claim 1, wherein said III-V compound semiconductor in said active layer includes at least gallium element as a III group member, and further includes at least arsenic element as a V group member.

12. The semiconductor optical device according to claim 3, wherein each of said first and said second SCH semiconductor layers is constituted by at least one of an Al_{X}Ga_{1-X}As semiconductor (0≦X≦1) and a Ga_{X}In_{1-X}As_{Y}P_{1-Y} semiconductor.

13. The semiconductor optical device according to claim 1, wherein said surface of said GaAs semiconductor is provided by one of a GaAs semiconductor layer or a gallium arsenide substrate.

14. The semiconductor optical device according to claim 1, wherein said semiconductor optical device includes at least one of a semiconductor laser, a semiconductor optical amplifier device, and an electroabsorption type modulator.

15. A semiconductor optical device comprising:
a first semiconductor layer of a first conductivity type provided on a surface of GaAs semiconductor;
an active layer provided on said first semiconductor layer, said active layer having a primary surface, said primary surface has a first area and second areas, said first area is provided between said second areas;
a second semiconductor layer of a second conductive type provided on said first area of said active layer, said second semiconductor layer having a pair of side faces; and
a current block semiconductor portion provided on said second areas of said active layer;
wherein said current block semiconductor portion has first and second current block semiconductor layers;
wherein said first current block semiconductor layer has a conductivity type different from that of said second current block semiconductor layer;
wherein said current block semiconductor portion is provided on said pair of side faces of said second semiconductor layer; and
wherein a refractive index of said second semiconductor layer is greater than refractive indices of said first and second current block semiconductor layers.

16. The semiconductor optical device according to claim 15, wherein said active layer is constituted by a III-V compound semiconductor containing at least nitrogen element as a V group member.

17. The semiconductor optical device according to claim 15, wherein said active layer is provided to generate light having a wavelength of longer than 0.9 micrometers.

18. The semiconductor optical device according to claim 15, further comprising a third semiconductor layer including a III-V compound semiconductor, said third semiconductor layer being provided between said active layer and at least one of said first and said second semiconductor layers;
wherein said III-V compound semiconductor exhibits a photoluminescence wavelength value between a photoluminescence wavelength value exhibited by said active layer and a photoluminescence wavelength value exhibited by said first and said second semiconductor layers.

19. The semiconductor optical device according to claim 15, further comprising a first SCH semiconductor layer provided between said active layer, and said current block semiconductor portion and said second semiconductor layer; and
a second SCH semiconductor layer provided between said active layer and said first semiconductor layer.

20. The semiconductor optical device according to claim 19, further comprising a third semiconductor layer including a III-V compound semiconductor, said third semiconductor layer being provided between said first SCH semiconductor layer and said second semiconductor layer;
wherein said III-V compound semiconductor exhibits a photoluminescence wavelength value between a photoluminescence wavelength value exhibited by said first SCH layer and a photoluminescence wavelength value exhibited by said second semiconductor layer.

21. The semiconductor optical device according to claim 19, further comprising a third semiconductor layer including a III-V compound semiconductor, said third semiconductor layer being provided between said second SCH semiconductor layer and said first semiconductor layer;
wherein said III-V compound semiconductor exhibits a photoluminescence wavelength value between a photoluminescence wavelength value exhibited by said second SCH layer and a photoluminescence wavelength value exhibited by said first semiconductor layer.

22. The semiconductor optical device according to claim 15, further comprising an etching stop layer provided between said active layer and said second semiconductor layer.

23. The semiconductor optical device according to claim 22, wherein said etching stop layer has a pair of side faces; and
wherein said current block semiconductor portion is provided on each side face of said etching stop layer.

24. The semiconductor optical device according to claim 15, further comprising a fourth semiconductor layer and a contact layer, said fourth semiconductor layer being provided on said second semiconductor layer and said current block semiconductor portion, and said contact layer being provided on said fourth semiconductor layer.

25. The semiconductor optical device according to claim 15, wherein each of said second and fourth semiconductor layers and first and second current block semiconductor layers is constituted by an (Al_{X}Ga_{1-X})_{Y}In_{1-Y}P semiconductor (0≦X≦1).

26. The semiconductor optical device according to claim 15, wherein each of said second and fourth semiconductor layers and first and second current block semiconductor layers is constituted by an Al_{X}Ga_{1-X}As semiconductor (0≦X≦1).

27. The semiconductor optical device according to claim 15, wherein said III-V compound semiconductor in said active layer includes at least gallium element as a III group member, and further includes at least arsenic element as a V group member.

28. The semiconductor optical device according to claim 19, wherein each of said first and said second SCH semiconductor layers is constituted by at least one of an Al_{X}Ga_{1-X}As semiconductor (0≦X≦1) and a Ga_{X}In_{1-X}As_{Y}P_{1-Y} semiconductor.

29. The semiconductor optical device according to claim 15, wherein said surface of said GaAs semiconductor is provided by one of a GaAs semiconductor layer and a gallium arsenide substrate.

30. The semiconductor optical device according to claim 15, wherein said semiconductor optical device includes at least one of a semiconductor laser, a semiconductor optical amplifier, and an electroabsorption type modulator.
